(19) United States
(12) Patent Application Publication
(10) Pub. No.: US 2025/0359267 A1
(43) Pub. Date: Nov. 20, 2025

(54) SEMICONDUCTOR DEVICE

(71) Applicant: Samsung Electronics Co., Ltd., Suwon-si (KR)

(72) Inventors: SANGHYUN KIM, Suwon-si (KR); JAEJOON OH, Suwon-si (KR); IN JUN HWANG, Suwon-si (KR)

(21) Appl. No.: 19/028,420

(22) Filed: Jan. 17, 2025

(30) Foreign Application Priority Data
May 17, 2024 (KR) 10-2024-0064748

(51) Int. Cl. H10D 64/27; H10D 30/47; H10D 62/85; H10D 64/66

(52) U.S. Cl. CPC H10D 64/411; H10D 30/4732; H10D 62/8503; H10D 64/667

(57) ABSTRACT

An embodiment provides a semiconductor device including: a channel layer; a barrier layer disposed on the channel layer and including a material having an energy band gap different from that of the channel layer; a gate semiconductor layer disposed on the barrier layer; a gate structure including a first gate electrode disposed on the gate semiconductor layer and a second gate electrode disposed between the first gate electrode and the gate semiconductor layer, and a source electrode and a drain electrode disposed on both sides of the gate structure and connected to the channel layer, wherein the first gate electrode includes a first curved surface between an upper surface and a side surface of the first gate electrode, and a second curved surface between a lower surface and a side surface of the first gate electrode, and a curvature of the first curved surface is smaller than that of the second curved surface.

### CROSS-REFERENCE TO RELATED APPLICATION

This application claims priority to and the benefit of Korean Patent Application No. 10-2024-0064748 filed in the Korean Intellectual Property Office on May 17, 2024, the entire contents of which are incorporated herein by reference.

### BACKGROUND

### 1. Field

The present disclosure relates to a semiconductor device.

### 2. Description of the Related Art

In modern society, semiconductor devices are closely related to daily life. Particularly, the importance of semiconductor devices used in various fields such as transportation fields such as electric vehicles, railroads, and electric trams, renewable energy systems such as solar power generation and wind power generation, and mobile devices is gradually increasing. Such semiconductor devices are used to handle high voltage or high current, and perform functions such as power conversion and control large power systems or high-output electronic devices. The semiconductor devices have the ability and durability to handle high power, so they may handle large amounts of current and withstand high voltage. For example, the semiconductor devices may handle voltages from hundreds of volts to thousands of volts and currents from tens of amperes to thousands of amperes. The semiconductor devices may improve the efficiency of electrical energy by minimizing power loss. In addition, the semiconductor devices may be stably driven even in environments such as high temperatures.

These semiconductor devices may be classified according to materials, for example, may be classified into a silicon carbide (SIC) semiconductor device and a gallium nitride (GaN) semiconductor device. By manufacturing the semiconductor devices using SiC or GaN instead of existing silicon (Si) wafers, the disadvantages of silicon having unstable characteristics at high temperatures may be compensated. The GaN semiconductor device may require high costs, but may be efficient in terms of speed and be suitable for high-speed charging of mobile devices.

### SUMMARY

Exemplary embodiments provide a semiconductor device with stable electrical characteristics and improved reliability.

An embodiment provides a semiconductor device including a channel layer; a barrier layer disposed on the channel layer and including a material having an energy band gap different from that of the channel layer; a gate semiconductor layer disposed on the barrier layer; a gate electrode pattern including a first gate electrode disposed on the gate semiconductor layer and a second gate electrode disposed between the first gate electrode and the gate semiconductor layer; and a source electrode and a drain electrode disposed on both sides of the gate electrode pattern respectively and in contact with the channel layer. The first gate electrode includes a lower surface facing the gate semiconductor layer, an upper surface extending horizontally in a first direction and arranged oppositely to the lower surface in a second direction crossing the first direction, a side surface extending vertically the first direction, a first curved surface between the upper surface and the side surface of the first gate electrode, and a second curved surface between the lower surface and the side surface of the first gate electrode. A curvature of the first curved surface is smaller than that of the second curved surface.

Another embodiment provides a semiconductor device including a channel layer; a barrier layer disposed on the channel layer and including a material having an energy band gap different from that of the channel layer; a gate semiconductor layer disposed on the barrier layer; a gate electrode pattern including a first gate electrode disposed on the gate semiconductor layer and a second gate electrode disposed between the first gate electrode respectively and the gate semiconductor layer; and a source electrode and a drain electrode disposed on both sides of the gate electrode pattern and in contact with the channel layer. The first gate electrode includes a lower surface facing the gate semiconductor layer, an upper surface extending horizontally in a first direction and arranged oppositely to the lower surface in a second direction crossing the first direction, and a side surface extending vertically the first direction. In a vertical cross-sectional view, a width of the first gate electrode or a width of the second gate electrode is greater than that of the gate semiconductor layer.

Another embodiment provides a semiconductor device including a channel layer containing GaN; a barrier layer disposed on the channel layer and containing AlGaN; a gate semiconductor layer disposed on the barrier layer and include p-type GaN; a gate electrode pattern including a first gate electrode disposed on the gate semiconductor layer and a second gate electrode disposed between the first gate electrode and the gate semiconductor layer and protruding from a side surface of the gate semiconductor layer; a source electrode and a drain electrode disposed on both sides of the gate electrode pattern respectively and in contact with the channel layer; and a passivation layer covering the barrier layer and the gate electrode pattern. The first gate electrode includes a lower surface facing the gate semiconductor layer, an upper surface extending in a first direction and arranged oppositely to the lower surface in a second direction crossing the first direction, a side surface extending the first direction, a first curved surface between the upper surface and the side surface of the first gate electrode, and a second curved surface between the lower surface and the side surface of the first gate electrode. A curvature of the first curved surface is smaller than that of the second curved surface.

According to the embodiments, it is possible to improve electrical characteristics of a semiconductor device.

### BRIEF DESCRIPTION OF THE DRAWINGS

FIG. 1 and FIG. 2 illustrate cross-sectional views of a semiconductor device according to an embodiment.

FIG. 3 illustrates an enlarged cross-sectional view of region Q1 of FIG. 1.

FIG. 4 to FIG. 12 illustrate cross-sectional views of semiconductor devices according to some embodiments.

FIG. 13A to FIG. 13C illustrate cross-sectional views of portions of semiconductor devices according to some embodiments.

FIG. 14 to FIG. 18 and FIG. 21 to FIG. 23 illustrate cross-sectional views of a process sequence to form a semiconductor device according to an embodiment.

FIG. 19 is an enlarged cross-sectional view of region Q2 of FIG. 18, and FIG. is an enlarged cross-sectional view illustrating a subsequent step to the process step described with FIG. 19.

FIG. 24 to FIG. 28 are cross-sectional views illustrating process steps for forming a semiconductor device according to another embodiment. FIG. 29 to FIG. 31 are cross-sectional views illustrating process steps for forming a semiconductor device according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The disclosure provides details of alternative examples, but such listing of alternatives is not exhaustive. Furthermore, any consistency of detail between various examples should not be interpreted as requiring such detail-it is impracticable to list every possible variation for every feature described herein. The language of the claims should be referenced in determining the requirements of the invention. In order to clearly describe the present disclosure, identical or similar elements throughout the specification may be denoted by the same reference numerals. For example, in drawings and discussion thereon below, items common may retain the same or similar reference designation, unless the context clearly indicates otherwise. Accordingly, the present disclosure may repeat reference numerals and/or letters in the various examples and drawings, such that like reference numerals and/or letters between figures indicate like items, elements, steps and so on. Accordingly, contents duplicate with what have been described one drawing may be briefly described or descriptions thereof may be omitted for the purpose of simplicity and clarity.

Further, in the drawings, the size and thickness of each element are arbitrarily illustrated for ease of description, and the present disclosure is not necessarily limited to those illustrated in the drawings. In the drawings, the size and relative sizes of items (e.g., thicknesses of layers, films, panels, regions, areas, etc.) may be exaggerated for clarity. For example, in the drawings, for ease of description, the thicknesses of some layers and areas or regions may be exaggerated. The figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present (at their point of contact). Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Throughout the specification, when a component is described as “including” or “containing” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

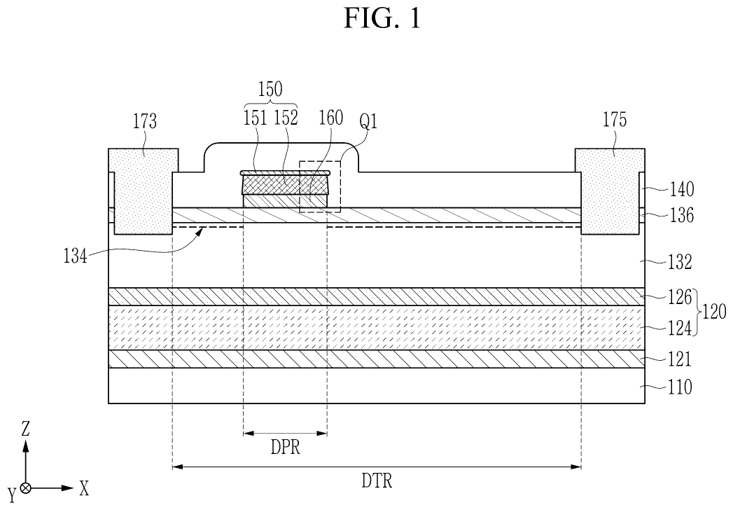

Hereinafter, a semiconductor device according to an embodiment will be described with reference to FIG. 1 to FIG. 3. For example, the semiconductor device may be a high electron mobility transistor (HEMT) which utilizes a quantum well and generally is used in high-speed and low-noise applications.

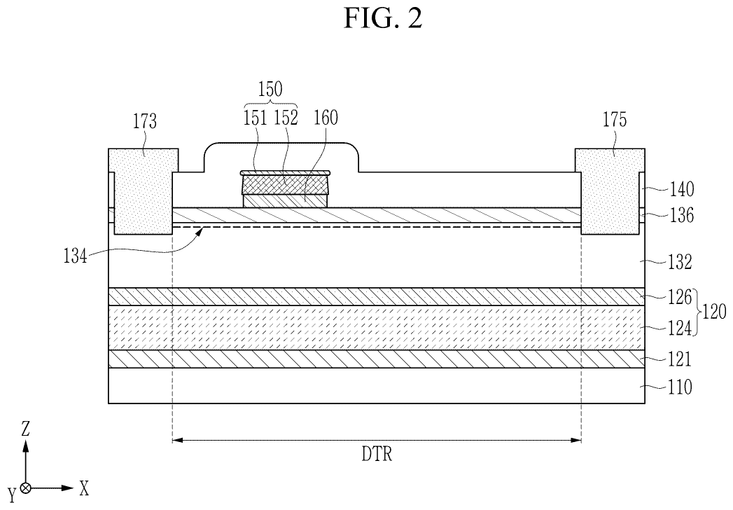

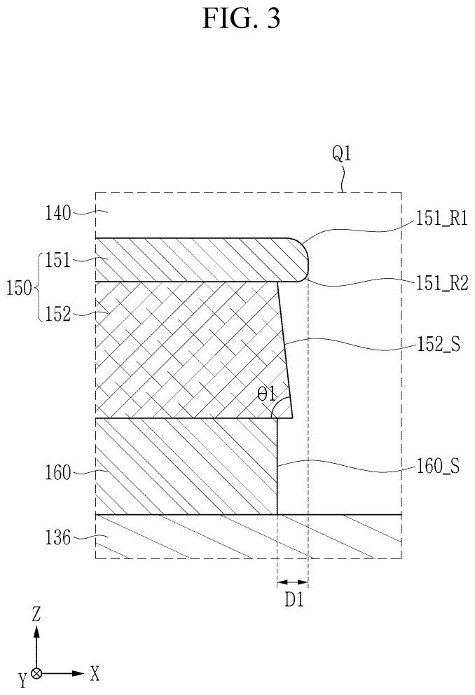

FIG. 1 and FIG. 2 illustrate cross-sectional views of a semiconductor device according to an embodiment. FIG. 3 illustrates an enlarged cross-sectional view of region Q1 of FIG. 1. FIG. 1 illustrates a case in which a semiconductor device according to an embodiment is in an off state, and FIG. 2 illustrates a case in which a semiconductor device according to an embodiment is in an on state.

Referring to FIG. 1, a semiconductor device according to an embodiment may include a channel layer 132, a barrier layer 136 disposed on the channel layer 132, a gate semiconductor layer 160 disposed on the barrier layer 136, and a gate structure 150 disposed on the gate semiconductor layer 160. A source electrode 173 and a drain electrode 175 may be disposed on both sides of the gate structure 150, respectively.

The channel layer 132 is a layer in which a channel between the source electrode 173 and the drain electrode 175 may be formed. A 2-dimensional electron gas (2DEG) 134 may be disposed (or induced) in the channel layer 132. The 2-dimensional electron gas 134 is a plurality of charge transport carriers in view of solid-state physics, and refers to a group of electrons that can move freely in two dimensions (for example, in the x-y-plane direction) but cannot move in another dimension (for example, in the z-direction) and are tightly bound in two dimensions. For example, the 2-dimensional electron gas 134 may exist in a 2-dimensional paper-like form within a 3-dimensional space. The 2-dimensional electron gas 134 may be induced in a semiconductor heterojunction structure. In the semiconductor device according to the present embodiment, the 2-dimensional electron gas 134 may be induced in proximity to an interface between the channel layer 132 and the barrier layer 136. For example, the 2-dimensional electron gas 134 may be generated in a portion adjacent to the barrier layer 136 within the channel layer 132. The channel layer 132 may include one or more materials selected from Group III-V materials, for example, nitrides including Al, Ga, In, B, or a combination thereof. The channel layer 132 may be a single layer or a multilayer (a composite layer including a plurality of layers). The channel layer 132 may be AlₓIn_{y}Ga_{1-x-y}N (0≤x≤1, 0≤y≤1, x+y≤1). For example, the channel layer 132 may include AlN, GaN, InN, InGaN, AlGaN, AlInN, AlInGaN, or a combination thereof. The channel layer 132 may be a layer doped with charge carrier impurities or an undoped layer (or not including a substantial number of impurities). A thickness of the channel layer 132 may be about several hundred nm or less.

The channel layer 132 may be disposed on a substrate 110, A seed layer 121 and buffer layer 120 may be disposed between the substrate 110 and the channel layer 132. The substrate 110, the seed layer 121, and the buffer layer 120 are layers required to readily ensure high quality of the channel layer 132.

In some embodiments, a semiconductor device may not include at least one of the substrate 110, the seed layer 121, and the buffer layer 120. For example, the substrate 110, the seed layer 121, and the buffer layer 120 may not be formed such that the channel layer 132 formed of GaN may act as both a transistor's channel and a substrate of the semiconductor device. In this case, the manufacturing cost may be higher than that of the semiconductor device according to the embodiment using the substrate 110, the seed layer 121 and the buffer layer 120.

The channel layer 132 including GaN may be grown using (on) the substrate 110. The substrate 110 may be made of Si. Generally, it may not be easy to grow the channel layer 132 directly on the substrate 110, because a lattice structure of Si and a lattice structure of GaN are different. Accordingly, the seed layer 121 and the buffer layer 120 may be first grown on the substrate 110, and then the channel layer 132 may be grown on the buffer layer 120.

In some embodiments, at least one of the substrate 110, the seed layer 121, and the buffer layer 120 may be used in the manufacturing process and then removed from the final structure of the semiconductor device. For example, after the channel layer 132 may be grown using the substrate 110, the seed layer 121 and the buffer layer 120, the substrate 110, the seed layer 121, and the buffer layer 120 may be removed.

The substrate 110 may include a semiconductor material. For example, the substrate 110 may include sapphire, Si, SiC, AlN, GaN, or a combination thereof. The substrate 110 may be a silicon on insulator (SOI) substrate. However the invention is not limited thereto, and the substrate 110 may be or include various kinds of material or structure types of substrates, which are all generally used in the industry. In some cases, the substrate 110 may include an insulating material. For example, several layers, including the channel layer 132, may be first formed on a semiconductor substrate, and then the semiconductor substrate may be removed and replaced with an insulating substrate.

The seed layer 121 may be disposed directly on the substrate 110. However, the present invention is not limited thereto, and another predetermined layer may be further disposed between the substrate 110 and the seed layer 121. The seed layer 121 is a layer that serves as a seed for growing the buffer layer 120, and may be formed of a crystal lattice structure that becomes the seed of the buffer layer 120. The buffer layer 120 may be disposed directly on the seed layer 121. However, the present invention is not limited thereto, and another predetermined layer may be further disposed between the seed layer 121 and the buffer layer 120. The seed layer 121 may include one or more materials selected from Group III-V materials, for example, nitrides including Al, Ga, In, B, or a combination thereof. The seed layer 121 may be AlxInyGa1-x-yN(0≤x≤1, 0≤y≤1, x+y≤1). For example, the seed layer 121 may include AlN, GaN, InN, InGaN, AlGaN, AlInN, AlInGaN, or a combination thereof.

The buffer layer 120 may be disposed on the seed layer 121. The buffer layer 120 may be disposed between the seed layer 121 and the channel layer 132. The buffer layer 120 may be a layer to alleviate the difference in lattice constant and thermal expansion coefficient between the seed layer 121 and the channel layer 132, or to prevent a parasitic current (leakage current) from flowing through the channel layer 132. The buffer layer 120 may include one or more materials selected from Group III-V materials, for example, nitrides including Al, Ga, In, B, or a combination thereof. The buffer layer 120 may be AlₓIn_{y}Ga_{1-x-y}N(0≤x≤1, 0≤y≤1, x+y≤1). For example, the buffer layer 120 may include AlN, GaN, InN, InGaN, AlGaN, AlInN, AlInGaN, or a combination thereof.

The buffer layer 120 of the semiconductor device according to the embodiment may include a superlattice layer 124 disposed on the seed layer 121, and a high resistance layer 126 disposed on the superlattice layer 124. The superlattice layer 124 and the high resistance layer 126 may be sequentially disposed on the substrate 110.

The superlattice layer 124 may be disposed on the seed layer 121. The superlattice layer 124 may be disposed directly on the seed layer 121. However, the present invention is not limited thereto, and another predetermined layer may be further disposed between the seed layer 121 and the superlattice layer 124. The superlattice layer 124 is a layer for alleviating the difference in lattice constant and thermal expansion coefficient between the substrate 110 and the channel layer 132, thereby alleviating tensile stress and compressive stress generated between the substrate 110 and the channel layer 132, and alleviating stress between all layers formed by growth in the final structure of the semiconductor device according to the embodiment. The superlattice layer 124 may include one or more materials selected from Group III-V materials, for example, nitrides including Al, Ga, In, B, or a combination thereof. The superlattice layer 124 may be AlₓIn_{y}Ga_{1-x-y}N(0≤x≤1, 0≤y≤1, x+y≤1). For example, the superlattice layer 124 may include AlN, GaN, InN, InGaN, AlGaN, AlInN, AlInGaN, or a combination thereof.

In the embodiment, the superlattice layer 124 may be a composite layer and include multiple layers in which layers containing different materials are alternately stacked. For example, the superlattice layer 124 may have a structure in which a layer made of AlGaN and a layer made of AlN are repeatedly stacked. For example, AlGaN/AlN/AlGaN/AlGaN/AlGaN/AlN may be sequentially stacked to form a superlattice layer. The number of AlGaN layers and GaN layers configuring the superlattice layer 124 may be variously changed, and the material configuring the superlattice layer 124 may be variously changed. For example, the superlattice layer 124 may have a structure in which a layer made of AlGaN and a layer made of GaN are repeatedly stacked. For example, AlGaN/GaN/AlGaN/GaN/AlGaN/GaN may be sequentially stacked to form a superlattice layer. In an example embodiment, when the superlattice layer 124 includes GaN, InN, AlGaN, AlInN, InGaN, AlN, AlN, AlInGaN, or a combination thereof, the superlattice layer 124 may have n-type semiconductor characteristics in which the concentration of electrons is greater than the concentration of holes, but the invention is not limited thereto.

In semiconductor technology, if a semiconductor material contains both p-type and n-type impurities, the conductivity-type of the semiconductor material will be determined by which type of impurity is in greater concentration. Therefore, if a semiconductor material has both p-type and n-type impurities, the net conductivity type will be determined by the dominant impurity concentration. As used herein, a material or a layer of a “first conductivity-type” (e.g., n-type) denotes that the dominant impurities in the semiconductor region is (or are) a first conductivity-type (e.g., n-type) impurity, and a “concentration” of impurities, electrons or holes refers the net concentration.

The high resistance layer 126 may be disposed on the superlattice layer 124. The high resistance layer 126 may be disposed directly on the superlattice layer 124. However, the present invention is not limited thereto, and another predetermined layer may be further disposed between the superlattice layer 124 and the high resistance layer 126. The high resistance layer 126 may be disposed between the superlattice layer 124 and the channel layer 132. The high resistance layer 126 is a layer for preventing a leakage current from flowing through the channel layer 132, thereby preventing the semiconductor device according to the embodiment from deteriorating. For example, the high resistance layer 126 may be made of a material with low-conductivity to electrically insulate the substrate 110 and the channel layer 132. The high-resistance layer may include one or more materials selected from Group III-V materials, for example, nitrides including Al, Ga, In, B, or a combination thereof. The high resistance layer 126 may be AlₓIn_{y}Ga_{1-x-y}N(0≤x≤1, 0≤y≤1, x+y≤1). For example, the high resistance layer 126 may include AlN, GaN, InN, InGaN, AlGaN, AlInN, AlInGaN, or a combination thereof. The high resistance layer 126 may be a single layer (e.g., a single homogenous layer formed of the same base layer throughout) or a multilayer. In an example embodiment, when the high resistance layer 126 includes GaN, InN, AlGaN, AlInN, InGaN, AlN, AlN, AlInGaN, or a combination thereof, the high resistance layer 126 may have n-type semiconductor characteristics in which the concentration of electrons is greater than the concentration of holes, but the invention is not limited thereto.

The barrier layer 136 may be disposed on the channel layer 132. The barrier layer 136 may be disposed directly on the channel layer 132. However, the present invention is not limited thereto, and another predetermined layer may be further disposed between the channel layer 132 and the barrier layer 136. The region of the channel layer 132 that overlaps the barrier layer 136 between the source electrode 173 and the drain electrode 175 may be a drift region DTR. The drift region DTR may be disposed between the source electrode 173 and the drain electrode 175. The drift region DTR may be a region in which a carrier moves when a potential difference occurs between the source electrode 173 and the drain electrode 175.

The semiconductor device according to the embodiment may be turned on/off according to whether a voltage is applied to the gate structure 150 and/or the magnitude of the voltage applied to the gate structure 150. When the semiconductor device is turned on, carrier movement may occur in the drift region DTR. When the semiconductor device is turned off, carrier movement may not occur in the drift region DTR.

The barrier layer 136 may include one or more materials selected from Group III-V materials, for example, nitrides including Al, Ga, In, B, or a combination thereof. The barrier layer 136 may be AlxInyGa1-x-yN(0≤x≤1, 0≤y≤1, x+y≤1). The barrier layer 136 may include GaN, InN, AlGaN, AlInN, InGaN, AlN, AlInGaN, or a combination thereof. An energy band gap of barrier layer 136 may be adjusted by a composition ratio of aluminum (Al) and/or indium (In) included in the barrier layer 136. The barrier layer 136 may be doped with a predetermined impurity. In this case, the impurity doped in the barrier layer 136 may be a p-type dopant such that holes may be majority carries. For example, the barrier layer 136 may be or include a p-type semiconductor material (e.g., p-type GaN). The impurity doped in the barrier layer 136 may be magnesium (Mg). By increasing or decreasing the impurity doping concentration of the barrier layer 136, the threshold voltage, temperature resistance, and the like of the semiconductor device according to the embodiment may be adjusted.

As atoms are brought together to form a semiconductive material, the electrons of each atom are acted on in such a way that the Pauli exclusion principle is obeyed, i.e., no two electrons in the material are allowed to have the same energy. This principle requires the existence of bands of allowed energies for electrons, with the bands typically separated by disallowed energy bands. The outermost band, which has the potential to be filled with electrons, is terminated by a valence band edge, and is separated from a conduction band by a disallowed energy band. In ideal semiconductor materials (no impurities) electrons do not have energies between the valence band edge and the conduction band edge, the disallowed energy band. The range of disallowed energies between the valence band edge and the conduction band edge is termed the energy band gap.

The barrier layer 136 may include a semiconductor material with characteristics different from those of the channel layer 132. The barrier layer 136 may be different from the channel layer 132 in at least one of polarization characteristics, energy band gap, and lattice constant. For example, the barrier layer 136 may include a material having an energy band gap different from that of the channel layer 132. In this case, the barrier layer 136 may have a higher energy band gap than the channel layer 132, and may have a higher electrical polarization rate than the channel layer 132. By the barrier layer 136, the 2-dimensional electron gas 134 may be induced in a region (or regions) of the channel layer 132 having a relatively low electrical polarization rate, In this regard, the barrier layer 136 may be referred to as a channel supply layer or a two-dimensional electron gas supply layer. The two-dimensional electron gas 134 may be formed within a portion of the channel layer 132 disposed below the interface between the channel layer 132 and the barrier layer 136. The two-dimensional electron gas 134 may have very high electron mobility.

The barrier layer 136 may be a single layer or a multilayer. When the barrier layer 136 is a multilayer, the material of respective layers configuring the multilayer may have different energy band gaps. In this case, several sub-layers configuring the barrier layer 136 may be disposed such that the energy band gap increases (widen) as the barrier layer 136 is closer to the channel layer 132. For example, the sub-layer closest to the channel layer 132 may be configured to have an energy band gap greater than those of the other sub-layers.

The gate semiconductor layer 160 may be disposed on the barrier layer 136. For example, the gate semiconductor layer 160 may contact the upper surface of the barrier layer 136. The gate semiconductor layer 160 may be disposed between the barrier layer 136 and the gate structure 150, which will be described later. The gate semiconductor layer 160 may be disposed between the source electrode 173 and the drain electrode 175. The gate semiconductor layer 160 may be spaced apart from the source electrode 173 and the drain electrode 175. The gate semiconductor layer 160 may be disposed closer to the source electrode 173 than the drain electrode 175. For example, the separation distance between the gate semiconductor layer 160 and the source electrode 173 may be smaller than the separation distance between the gate semiconductor layer 160 and the drain electrode 175, but the invention is not limited thereto.

The gate semiconductor layer 160 may include one or more materials selected from Group III-V materials, for example, nitrides including Al, Ga, In, B, or a combination thereof. The gate semiconductor layer 160 may be AlxInyGa1-x-yN(0≤x≤1, 0≤y≤1, x+y≤1). For example, the gate semiconductor layer 160 may include AlN, GaN, InN, InGaN, AlGaN, AlInN, AlInGaN, or a combination thereof. The gate semiconductor layer 160 may include a material having an energy band gap different from that of the barrier layer 136. For example, the gate semiconductor layer 160 may include GaN, and the barrier layer 136 may include AlGaN. The gate semiconductor layer 160 may be doped with a predetermined impurity. In this case, the impurity doped in the gate semiconductor layer 160 may be a p-type dopant such that a majority carrier is a hole. For example, the gate semiconductor layer 160 may include GaN doped with a p-type impurity. For example, the gate semiconductor layer 160 may be comprised as (formed of or include) a p-GaN (p-type GaN) layer. However, the invention is not limited thereto, and the gate semiconductor layer 160 may be a p-AlGaN (p-type AlGaN) layer. The gate semiconductor layer 160 may be a single layer or a multilayer.

A depletion region DPR may be provided in the channel layer 132 and may be defined by the gate semiconductor layer 160. For example, the depletion region DPR may be a region of the channel layer 132 that overlaps the gate semiconductor layer 160 as viewed from a vertical third direction (e.g., Z direction). The depletion region DPR may partially overlap the drift region DTR such that the depletion region DPR is disposed between two separate drift regions DTR and may have a narrower width than the drift region DTR. The gate semiconductor layer 160 having an energy band gap different from that of the barrier layer 136 may be disposed on the barrier layer 136 and on the depletion region DPR. Accordingly, a level of an energy band of a portion of the barrier layer 136 overlapping the gate semiconductor layer 160 may increase to induce an energy band offset (potential changes and bending in energy band diagrams). Accordingly, the depletion region DPR may be formed (induced) in a region of the channel layer 132 that overlaps the gate semiconductor layer 160 as viewed from a vertical third direction. The depletion region DPR may be a region in a channel path of the channel layer 132 in which the two-dimensional electron gas 134 is not formed in a normal state of the operation of the semiconductor device. The depletion region DPR may have a lower electron concentration than the other regions of the channel path. The depletion region DPR may mean a region in which the flow of the two-dimensional electron gas 134 is interrupted (or significantly reduced) within the drift region DTR during the normal state. For example, the depletion region DPR may result in substantially no current flow between the source electrode 173 and the drain electrode 175, and the channel path may be electrically blocked (or disconnected). Accordingly, the semiconductor device according to the embodiment may have a normally off characteristic.

For example, the semiconductor device according to the embodiment may be a normally off high electron mobility transistor (HEMT). As shown in FIG. 1 and described in detail later, in a normal state in which no voltage is applied to the gate structure 150), the depletion region DPR may exist, and the semiconductor device according to the embodiment may be in an off state. As shown in FIG. 2 and described in detail later, when a voltage higher than a threshold voltage is applied to the gate structure 150, the depletion region DPR disappears, and the two-dimensional electron gas 134 may be continuously induced in and along the entire portion of the drift region DTR without being interrupted. For example, the two-dimensional electron gas 134 may be formed throughout the channel path between the source electrode 173 and the drain electrode 175, and the semiconductor device according to the embodiment may be in an on state. In summary, the semiconductor device according to the embodiment may include first and second semiconductor layers having different electrical polarization characteristics from each other, and the first semiconductor layer (e.g., the barrier layer 136) having a relatively large (high) polarization rate may cause a two-dimensional electron gas 134 in the second semiconductor layer (e.g., the channel layer 132) heterogeneously junctioned to (and in contact with) the first semiconductor layer (e.g., the barrier layer 136) having a relatively large polarization rate.

The two-dimensional electron gas 134 may be used as a channel between the source electrode 173 and the drain electrode 175, and the continuation or interruption of the flow of the two-dimensional electron gas 134 may be controlled by the bias voltage applied to the gate structure 150. In the gate-off state, the flow of the two-dimensional electron gas 134 is blocked, so that no current may flow between the source electrode 173 and the drain electrode 175. In the gate-on state, as the two-dimensional electron gas 134 is continuously induced between the source electrode 173 and the drain electrode 175, a current may flow between the source electrode 173 and the drain electrode 175.

The case in which the semiconductor device according to the embodiment is a normally-off high electron mobility transistor has been described above, but the present invention is not limited thereto. For example, the semiconductor device according to the embodiment may be a normally-on high electron mobility transistor. In the case of a normally-on high electron mobility transistor, the gate semiconductor layer 160 may be omitted, and accordingly, the gate structure 150 to be described later may be disposed directly on the barrier layer 136. For example, the gate structure 150 to be described later may be in contact with the barrier layer 136. In this structure, the 2-dimensional electron gas 134 may be used as a channel in a state in which a voltage is not applied to the gate structure 150 to be described later, and a current flow may occur between the source electrode 173 and the drain electrode 175. In addition, when a negative voltage is applied to the gate structure 150 to be described later, the depletion region DPR in which the flow of the 2-dimensional electron gas 134 is blocked may be formed under the gate structure 150.

The seed layer 121, the superlattice layer 124, the high resistance layer 126, the channel layer 132, the barrier layer 136, and the gate semiconductor layer 160 described above may be sequentially stacked on the substrate 110. In some exemplary embodiments, at least one of the seed layer 121, the superlattice layer 124, the high resistance layer 126, the channel layer 132, the barrier layer 136, and the gate semiconductor layer 160 may be omitted.

In some exemplary embodiments, the seed layer 121, the superlattice layer 124, the high resistance layer 126, the channel layer 132, the barrier layer 136, and the gate semiconductor layer 160 may be made of the same base semiconductor material (e.g., AlxInyGa1-x-yN), and the material composition ratios (e.g., ratio between x, y and x) of respective layers may be different in consideration of roles and performance of respective layers required for the semiconductor device.

The gate structure 150 may be disposed on the gate semiconductor layer 160. For example, the gate semiconductor layer 160 may be disposed on the barrier layer 136, and the gate structure 150 may be disposed on the gate semiconductor layer 160. The gate structure 150 may be in Schottky contact or ohmic contact with the gate semiconductor layer 160. The gate structure 150 may overlap the gate semiconductor layer 160 in a vertical direction (for example, a thickness direction of the channel layer 132, hereinafter, a third direction (Z direction)). The upper surface of the gate semiconductor layer 160 may be entirely covered by the gate structure 150.

In some examples, the gate structure 150 may overlap a partial region of the barrier layer 136 in the third direction (Z direction). For example, the gate structure 150 may overlap at least a portion of the drift region DTR of the channel layer 132 in the third direction (Z direction).

The gate structure (e.g., a gate electrode pattern) 150 may be disposed between the source electrode 173 and the drain electrode 175. The gate structure 150 may be spaced apart from the source electrode 173 and the drain electrode 175. For example, the gate structure 150 may be disposed closer to the source electrode 173 than the drain electrode 175. For example, the separation distance between the gate structure 150 and the source electrode 173 may be smaller than the separation distance between the gate structure 150 and the drain electrode 175, but the present invention is not limited thereto.

In the embodiment, the gate structure 150 may entirely cover the gate semiconductor layer 160. For example, in a vertical cross-sectional view (as viewed from the Y), the width of the gate structure 150 in the first direction (X direction) may be greater than that of the gate semiconductor layer 160 in the first direction (X direction). Here, the width of the gate structure 150 in the first direction (X direction) may mean a maximum width of the gate structure 150 in the first direction (X direction) in the vertical cross-sectional view, and the width of the gate semiconductor layer 160 in the first direction (X direction) may mean a maximum width of the gate semiconductor layer 160 in the first direction (X direction) in the vertical cross-sectional view. In addition, at least a portion of the gate structure 150 may protrude from (protrude beyond) the side surface of the gate semiconductor layer 160 in a horizontal direction, for example, along the first direction (X direction). For example, the first gate electrode 151 and/or the second gate electrode 152 configuring the gate structure 150 may protrude from a side surface of the gate semiconductor layer 160 along the first direction (X direction). Accordingly, the gate structure 150 may serve to effectively disperse the electric field concentrated around the gate semiconductor layer 160.

Referring further to FIG. 3, the gate structure 150 may include a first gate electrode 151 disposed on the gate semiconductor layer 160 and a second gate electrode 152 disposed between the first gate electrode 151 and the gate semiconductor layer 160.

The first gate electrode 151 may include a lower surface facing the gate semiconductor layer 160, an upper surface extending horizontally in a first direction (X direction) and arranged oppositely to the lower surface in a second direction (Y direction) crossing the first direction, and a side surface extending vertically the first direction.

The first gate electrode 151 may be disposed on the gate semiconductor layer 160. The first gate electrode 151 may overlap the gate semiconductor layer 160 in the third direction (Z direction). The first gate electrode 151 may overlap a partial region of the barrier layer 136 in the third direction (Z direction). The first gate electrode 151 may overlap at least a portion of the drift region DTR of the channel layer 132 in the third direction (Z direction).

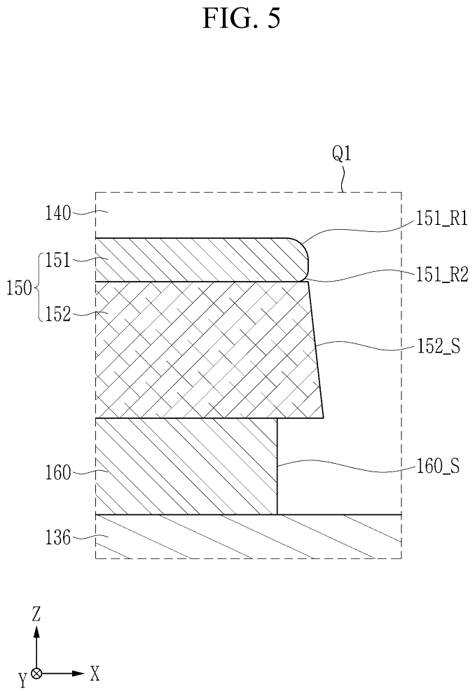

In the embodiment, the first gate electrode 151 may entirely cover the gate semiconductor layer 160. For example, in a vertical cross-sectional view (as viewed from the Y), the width of the first gate electrode 151 in the first direction (X direction) may be greater than that of the gate semiconductor layer 160 in the first direction (X direction). Here, the width of the first gate electrode 151 in the first direction (X direction) may mean a maximum width of the first gate electrode 151 in the first direction (X direction) in the vertical cross-sectional view, and the width of the gate semiconductor layer 160 in the first direction (X direction) may mean a maximum width of the gate semiconductor layer 160 in the first direction (X direction) in the vertical cross-sectional view. The first gate electrode 151 may include a lower surface facing the gate semiconductor layer 160, an upper surface extending in a direction (x-direction) and arranged opposite to the lower surface in another direction (e.g. Z-direction), and a side surface extending in the other direction. At least a portion of the first gate electrode 151 may protrude from the side surface 160_S of the gate semiconductor layer 160 in a horizontal direction, for example, along the first direction (X direction). In this case, a protrusion distance (first distance) D1 (a maximum distance from the side surface 160_S to the side surface of the first gate electrode 151 in the first direction (X direction)) at which the first gate electrode 151 protrudes from the side surface 160_S of the gate semiconductor layer 160 in the first direction (X direction) may be less than or equal to 1/10 of the width of the gate semiconductor layer 160 in the first direction (X direction), but the invention is not limited thereto. Accordingly, it may serve to effectively disperse the electric field concentrated around the gate semiconductor layer 160. However, the present invention is not limited thereto, and the first gate electrode 151 may not protrude from the side surface 160 S of the gate semiconductor layer 160. In this case, the second gate electrode 152 may protrude from the side surface 160_S of the gate semiconductor layer 160, as described later with reference to FIG. 5 and subsequent drawings of FIG. 5.

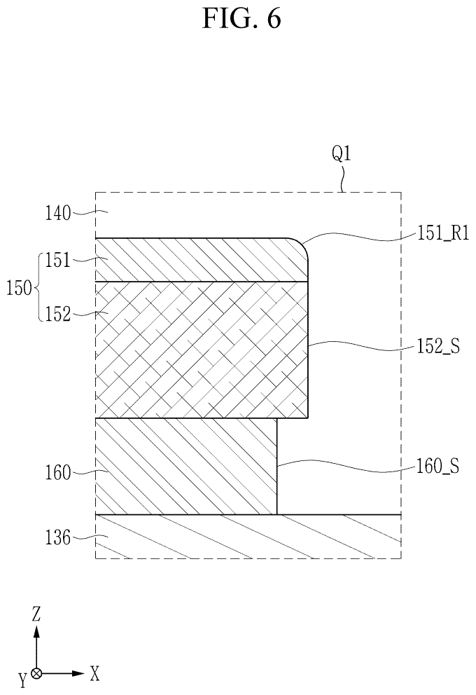

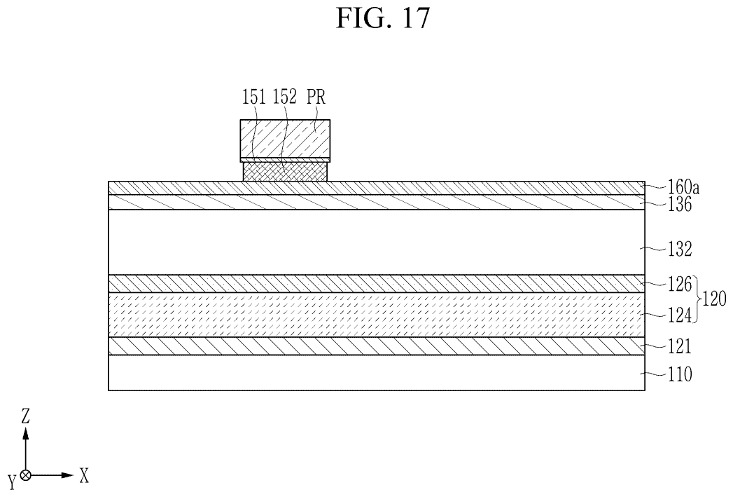

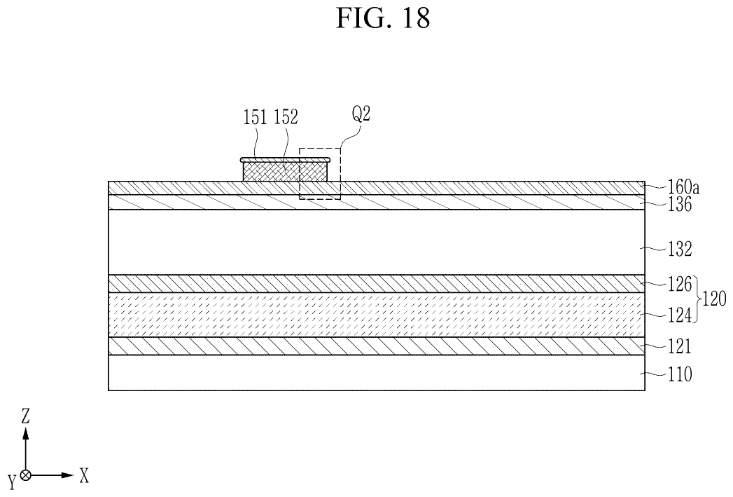

The first gate electrode 151 may include a first curved surface 151_R1 between the upper surface and the side surface of the first gate electrode 151 and a second curved surface 151_R2 between the lower surface and the side surface thereof. The first curved surface 151_R1 of the first gate electrode 151 and the second curved surface 151_R2 of the first gate electrode 151 may have curved surfaces. In this case, the curvature of the first curved surface 151_R1 of the first gate electrode 151 may be smaller than that of the second curved surface 151_R2 of the first gate electrode 151. This may be due to the process characteristics of patterning the gate semiconductor layer 160 after removing the photoresist (PR in FIG. 17) disposed on the first gate electrode 151 in the process of patterning the gate semiconductor layer 160. Accordingly, the first gate electrode 151 may serve to effectively disperse the electric field concentrated around the gate semiconductor layer 160 and/or the gate structure 150. However, the present invention is not limited thereto, and for example, the first curved surface 151_R1 of the first gate electrode 151 and the second curved surface 151_R2 of the first gate electrode 151 may include at least one inclined surface. For example, the side surface of the first gate electrode 151 may include multiple inclined surfaces with different inclinations. Alternatively, in some embodiments, the first gate electrode 151 may not include the second curved surface 151_R2 between the lower surface and the side surface. This will be described later with reference to FIG. 6.

The first gate electrode 151 may include a conductive material. For example, the first gate electrode 151 may include a metal, a metal alloy, a conductive metal nitride, a metal silicide, a doped semiconductor material, a conductive metal oxide, a conductive metal oxynitride, or the like. For example, the first gate electrode 151 may include, for example, at least one of a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride (TiAlN), a tantalum aluminum nitride (TaAlN), a tungsten nitride (WN), ruthenium (Ru), a titanium aluminum (TiAl), a titanium aluminum carbonitride (TiAlC—N), a titanium aluminum carbide (TiAlC), a titanium carbide (TiC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and a combination thereof, but the invention is not limited thereto. The first gate electrode 151 may be a single layer or a multilayer.

The second gate electrode 152 may be disposed between the first gate electrode 151 and the gate semiconductor layer 160. For example, the second gate electrode 152 may be disposed on the gate semiconductor layer 160, and the first gate electrode 151 may be disposed on the second gate electrode 152. The second gate electrode 152 may overlap the gate semiconductor layer 160 in the third direction (Z direction).

In the embodiment, the side surface 152_S of the second gate electrode 152 may have a first inclination angle θ1 with respect to the upper surface of the channel layer 132. In this case, the first inclination angle θ1 may be constant and may be an acute angle. For example, the second gate electrode 152 may have a tapered shape. The width of the second gate electrode 152 along the first direction (X direction) may gradually decrease as the distance from the upper surface of the channel layer 132 increases. However, the present invention is not limited thereto, and the width of the second gate electrode 152 in the first direction (X direction) may gradually increase or become constant as the distance from the upper surface of the channel layer 132 increases.

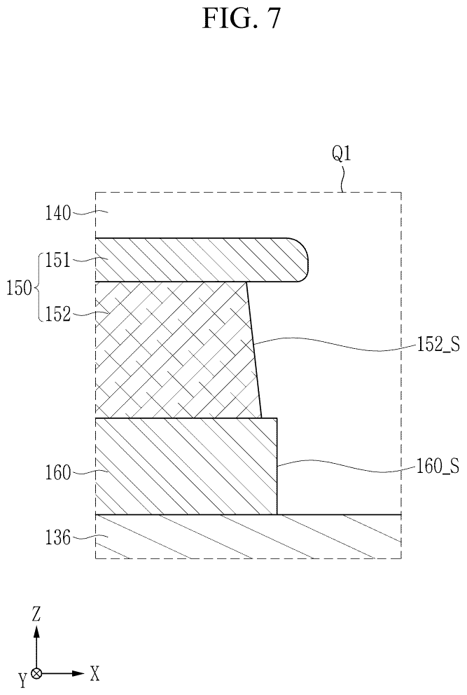

In the embodiment, the second gate electrode 152 may entirely cover the gate semiconductor layer 160. For example, in a vertical cross-sectional view, the width of the second gate electrode 152 in the first direction (X direction) may be greater than that of the gate semiconductor layer 160 in the first direction (X direction). Here, the width of the second gate electrode 152 in the first direction (X direction) may mean a maximum width of the second gate electrode 152 in the first direction (X direction) in the vertical cross-sectional view, and the width of the gate semiconductor layer 160 in the first direction (X direction) may mean a maximum width of the gate semiconductor layer 160 in the first direction (X direction). For example, as shown in FIG. 3, the width of the lower portion of the second gate electrode 152 in the first direction (X direction) may be greater than the maximum width of the gate semiconductor layer 160 in the first direction (X direction) in the vertical cross-sectional view. In addition, the second gate electrode 152 may protrude from the side surface 160_S of the gate semiconductor layer 160 in a horizontal direction, for example along the first direction (X direction).). In this case, the distance at which the second gate electrode 152 protrudes from the side surface 160 S of the gate semiconductor layer 160 in the first direction (X direction) may be less than or equal to 1/10 of the width of the gate semiconductor layer 160 in the first direction (X direction), but the invention is not limited thereto. For example, a protrusion distance (a maximum distance from the side surface 160_S to the side surface 152 S of the second gate electrode 152 in the first direction (X direction)) may be less than or equal to 1/10 of the width of the gate semiconductor layer 160 in the first direction (X direction). Accordingly, it may serve to effectively disperse the electric field concentrated around the gate semiconductor layer 160. However, the present invention is not limited thereto, and, for example, the second gate electrode 152 may not protrude from the side surface 160_S of the gate semiconductor layer 160. In this case, the first gate electrode 151 may protrude from the side surface 160_S of the gate semiconductor layer 160 as described later with reference to FIG. 7.

In the embodiment, the width of the second gate electrode 152 in the first direction (X direction) may be different from that of the first gate electrode 151 in the first direction (X direction) in a vertical cross-sectional view (as viewed from the Y). For example, the width of the second gate electrode 152 in the first direction (X direction) may be smaller than that of the first gate electrode in the first direction (X direction). The first gate electrode 151 may be produced in the first direction (X direction) from the side surface 152_S of the second gate electrode 152. However, the present invention is not limited thereto, and the width of the second gate electrode 152 in the first direction (X direction) may be greater than or equal to that of the first gate electrode in the first direction (X direction).

The second gate electrode 152 may include a conductive material. The second gate electrode 152 may include a material different from that of the first gate electrode 151. The second gate electrode 152 and the first gate electrode 151 may include materials with different etching rates (etched amount of the material per unit time with respect to a certain etching process). For example, each of the second gate electrode 152 and the first gate electrode 151 may include a material having an etch selectivity (or etching selectivity) to the other with respect to a certain specific etching process such that the ratio of the etching rates of two different materials of the second gate electrode 152 and the first gate electrode 151 is significantly high. For example, a certain specific etching process may remove a significant amount of the second gate electrode 152 while providing little or no removal of the first gate electrode 151. For example, the second gate electrode 152 may include a metal, a metal alloy, a conductive metal nitride, a metal silicide, a doped semiconductor material, a conductive metal oxide, a conductive metal oxynitride, or the like. However, the invention is not limited thereto, and the second gate electrode 152 may include the same material as the first gate electrode 151. The second gate electrode 152 may be a single layer or a multilayer.

The semiconductor device according to the embodiment may further include a passivation layer 140 disposed on the barrier layer 136 and the gate structure 150.

The passivation layer 140 may be disposed on the barrier layer 136 and the gate structure 150. The passivation layer 140 may cover upper and side surfaces of the gate structure 150 and side surfaces of the gate semiconductor layer 160. A lower surface of the passivation layer 140 may overlap with the barrier layer 136 and the gate structure 150. Accordingly, the barrier layer 136, the gate semiconductor layer 160, and the gate structure 150 may be protected by the passivation layer 140. However, the present invention is not limited thereto, and the gate structure 150 may penetrate the passivation layer 140, while connected to and in contact with the gate semiconductor layer 160, and the passivation layer 140 may not cover the upper surface of the gate structure 150.

Alternatively, the lower surface of the passivation layer 140 may be at least partially in contact with the gate semiconductor layer 160. The passivation layer 140 may include an insulating material. For example, the passivation layer 140 may include an oxide such as SiO2 or Al2O3. As another example, the passivation layer 140 may include a nitride such as SiN or an oxynitride such as SiON. The term “contact,” “contacting,” “contacts,” or “in contact with,” as used herein, refers to a direct connection (i.e., touching at the point of contact) unless the context clearly indicates otherwise.

FIG. 1 and FIG. 2 illustrate that the passivation layer 140 is formed as a single layer, but the present invention is not limited thereto, and the passivation layer 140 may be formed as a multilayer including different materials. In an example embodiment, an upper passivation layer covering at least some of the passivation layer 140, the source electrode 173, and the drain electrode 175 may be further included.

The source electrode 173 and the drain electrode 175 may be disposed on the channel layer 132. The source electrode 173 and the drain electrode 175 may be in contact with the channel layer 132, and may be electrically connected to the channel layer 132. The channel layer 132 may have recessed portions where the source electrode 173 and the drain electrode 175 are connected respectively.

The source electrode 173 and the drain electrode 175 may extend in the second direction (Y direction). The source electrode 173 and the drain electrode 175 may be spaced apart from each other, and the gate structure 150 and the gate semiconductor layer 160 may be disposed between the source electrode 173 and the drain electrode 175. The gate structure 150 and the gate semiconductor layer 160 may be spaced apart from the source electrode 173 and the drain electrode 175. For example, the source electrode 173 and the drain electrode 175 may be disposed on both sides of the gate structure 150, respectively. For example, the source electrode 173 may be electrically connected to the channel layer 132 at one side of the gate structure 150, and the drain electrode 175 may be electrically connected to the channel layer 132 at the other side of the gate structure 150. The source electrode 173 and the drain electrode 175 may be disposed outside the drift region DTR of the channel layer 132. The source electrode 173 and the drain electrode 175 may not overlap with the drift region DTR of the channel layer 132 as viewed from a vertical third direction (e.g., Z direction). A boundary surface between the source electrode 173 and the channel layer 132 may be adjacent to one edge of the drift region DTR. Likewise, a boundary surface between the drain electrode 175 and the channel layer 132 may be adjacent to the other edge of the drift region DTR.

However, the present invention is not limited thereto, and the source electrode 173 and drain electrode 175 may not be disposed on the outer surface of the drift region DTR of the channel layer 132. For example, the source electrode 173 and the drain electrode 175 may contact the upper surface of the barrier layer 136. In this case, the barrier layer 136 may have portions doped with impurities at a high concentration, and the doped portions may contact the source electrode 173 and the drain electrode 175 respectively. As another example, the source electrode 173 and the drain electrode 175 may be embedded in the barrier layer 136. As yet another example, the channel layer 132 may not be recessed, and the source electrode 173 and the drain electrode 175 may be disposed on the upper surface of the channel layer 132. In this case, the bottom surfaces of the source electrode 173 and the drain electrode 175 may contact the upper surface of the channel layer 132.

Though not shown in the drawings, a portion of the channel layer 132 contacting the source electrode 173 and the drain electrode 175 may be doped at a high concentration. In this case, the carrier passing through the 2-dimensional electron gas 134 may be transmitted to the source electrode 173 and the drain electrode 175 through the portion of the channel layer 132 doped at a high concentration, for example, the upper portion of the 2-dimensional electron gas 134. The source electrode 173 and the drain electrode 175 may not be in contact with the 2-dimensional electron gas 134 in a horizontal direction. Here, the horizontal direction may mean a direction parallel to the upper surface of the channel layer 132 or the barrier layer 136.

Trenches may be provided on both sides of the gate structure 150 to be spaced apart from each other. The trenches may penetrate the passivation layer 140 and the barrier layer 136, and may be recessed into upper portions of the channel layer 132. The source electrode 173 and the drain electrode 175 may be disposed in the trenches (141 and 143 in FIG. 22). The source electrode 173 and the drain electrode 175 may be formed to fill the trenches, respectively. The source electrode 173 and the drain electrode 175 may be in contact with the channel layer 132 and the barrier layer 136 in the trenches. The channel layer 132 may be disposed to cover (or to be exposed to) bottom surfaces and portions of sidewalls of the trenches. Accordingly, the source electrode 173 and the drain electrode 175 may be described as contacting the upper surface and the side surface (sidewall exposed by the trenches) of the channel layer 132. The barrier layer 136 and the passivation layer 140 may be disposed to surround (or to be exposed to) the sidewalls of the trenches. The source electrode 173 and the drain electrode 175 may contact the side surfaces of the barrier layer 136 and the passivation layer 140. The source electrode 173 and the drain electrode 175 may be described as covering the side surfaces of the channel layer 132 and the barrier layer 136.

In the embodiment, the source electrode 173 and the drain electrode 175 may cover at least a portion of the side surface (sidewalls exposed by the trenches) of the passivation layer 140. For example, the source electrode 173 and the drain electrode 175 may cover the side surface of the passivation layer 140. The upper surfaces of the source electrode 173 and the drain electrode 175 may protrude from the upper surfaces of the passivation layer 140. In addition, at least a portion of each of the source electrode 173 and the drain electrode 175 may cover at least a portion of the upper surface of the passivation layer 140. However, the present invention is not limited thereto, and the source electrode 173 and the drain electrode 175 may cover at least a portion of the side surface of the passivation layer 140 and may not cover the other portions of the side surface of the passivation layer 140. In this case, the other portion of the passivation layer 140 may be disposed at a higher level in the Z direction than the upper surfaces of the source electrode 173 and the drain electrode 175.

The source electrode 173 and the drain electrode 175 may include a conductive material. For example, the source electrode 173 and the drain electrode 175 may include a metal, a metal alloy, a conductive metal nitride, a metal silicide, a doped semiconductor material, a conductive metal oxide, a conductive metal oxynitride, or the like. For example, the source electrode 173 and the drain electrode 175 may include, for example, at least one of a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride (TiAlN), a tantalum aluminum nitride (TaAlN), a tungsten nitride (WN), ruthenium (Ru), a titanium aluminum (TiAl), a titanium aluminum carbonitride (TiAlC—N), a titanium aluminum carbide (TiAlC), a titanium carbide (TiC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and a combination thereof, but the invention is not limited thereto. The source electrode 173 and the drain electrode 175 may be a single layer or multilayer. The source electrode 173 and the drain electrode 175 may be in ohmic contact with the channel layer 132.

FIG. 1 and FIG. 2 illustrate that the semiconductor device according to the embodiment includes a pair of source electrodes 173 and drain electrodes 175, but the invention is not limited thereto. For example, the semiconductor device may include a plurality of source electrodes sequentially stacked in the third direction (Z direction) or arranged in the Y direction on the channel layer 132, and the drain electrode 175 may include a plurality of drain electrodes sequentially stacked in the third direction (Z direction) or arranged in the Y direction on the channel layer 132. Alternatively, each of the source electrode 173 and the drain electrode 175 may include three or more layers.

Though not shown in the drawings, the semiconductor device according to the embodiment may further include a field dispersion layer covering at least a portion of the passivation layer 140.

The field dispersion layer may be disposed between the source electrode 173 and the drain electrode 175. The field dispersion layer may cover the gate structure 150.

The field dispersion layer may overlap the gate structure 150 in the third direction (Z direction). The field dispersion layer may be electrically connected to the source electrode 173. For example, the field dispersion layer may be connected to the source electrode 173. The field dispersion layer may include the same material as the source electrode 173.

In some embodiments, the field dispersion layer may be disposed on the same layer as the source electrode 173. The field dispersion layer may be simultaneously formed in the same process as the source electrode 173. For example, a boundary between the field dispersion layer and the source electrode 173 may not be clear, and the field dispersion layer may be integrally formed with the source electrode 173. However, the invention is not limited thereto. The field dispersion layer and the source electrode 173 may be two distinct elements with a clearly defined boundary between them. In addition, the field dispersion layer may be disposed in a different layer from the source electrode 173, and may be formed in a different process. For example, the field dispersion layer may be a part of a first layer, and the source electrode 173 may be a part of a second layer, which is different from the first layer. The field dispersion layer may serve to disperse the electric field concentrated around the gate structure 150.

In the gate-off state, the two-dimensional electron gas 134 may be at a very high concentration in a portion of the channel layer 132 disposed between the gate structure 150 and the source electrode 173 and in a portion of the channel layer 132 disposed between the gate structure 150 and the drain electrode 175. In this case, an electric field may be concentrated on the gate structure 150 or the gate semiconductor layer 160. Meanwhile, the gate structure 150 and the gate semiconductor layer 160 are vulnerable to an electric field, so that when the electric field is concentrated, a leakage current may increase and a breakdown voltage of the transistor may decrease. However, by the field dispersion layer, the electric field concentrated around the gate structure 150 or the gate semiconductor layer 160 may be dispersed, so that the leakage current and the breakdown voltage may not be undesirably affected.

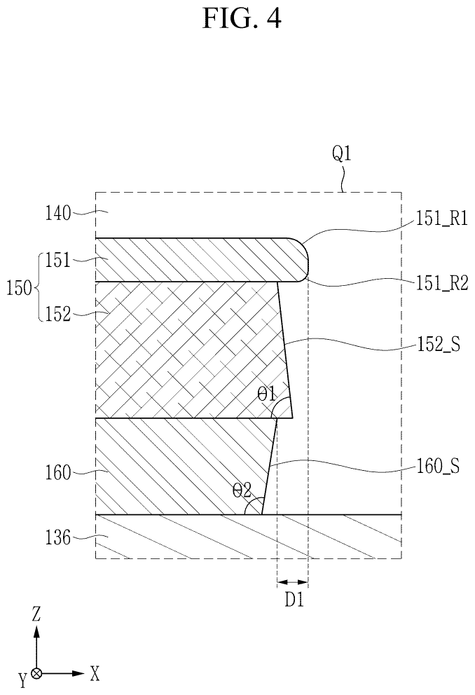

Hereinafter, a semiconductor device according to some other embodiments will be described with reference to FIG. 4 to FIG. 12.

FIG. 4 to FIG. 12 illustrate cross-sectional views of semiconductor devices according to some embodiments.

Referring to FIG. 4, the side surface 160_S of the gate semiconductor layer 160 of the semiconductor device according to some embodiments may have a second inclination angle θ2 with respect to the upper surface of the channel layer 132. In this case, the second inclination angle θ2 may be constant and may be an obtuse angle. For example, the gate semiconductor layer 160 may have an inverted tapered shape. The width of the gate semiconductor layer 160 in the first direction (X direction) may gradually increase as the distance from the upper surface of the channel layer 132 increases. In this case, the maximum width of the gate semiconductor layer 160 in the first direction (X direction) may be smaller than the maximum width of the first gate electrode 151 and the second gate electrode 152 in the first direction (X direction). For example, the width of the upper portion of the gate semiconductor layer 160 in the first direction (X direction) may be smaller than the maximum width of the first gate electrode 151 and the second gate electrode 152 in the first direction (X direction).

Referring to FIG. 5, in some embodiments, the width of the second gate electrode 152 in the first direction (X direction) may be greater than that of the first gate electrode in the first direction (X direction). The second gate electrode 152 may include a portion protruding from the side surface of the first gate electrode 151 in a first direction (X direction). In this case, the width of the second gate electrode 152 in the first direction (X direction) may gradually decrease as the distance from the upper surface of the channel layer 132 increases.

Referring to FIG. 6, in some embodiments, the width of the second gate electrode 152 in the first direction (X direction) may be substantially the same as that of the first gate electrode 151 in the first direction (X direction). In this case, the side surface of the first gate electrode 151 and the side surface 152_S of the second gate electrode 152 may extend in the third direction (Z direction), but the invention is not limited thereto. In addition, in some embodiments, the first gate electrode 151 may not include a second curved surface. For example, the first gate electrode 151 may include a first curved surface 151_R1 between the upper surface and the side surface of the first gate electrode 151, and may not include a curved surface between the lower surface and the side surface of the first gate electrode 151.

Referring to FIG. 7, in some embodiments, the width of the gate semiconductor layer 160 in the first direction (X direction) may be greater than the of the second gate electrode 152 in the first direction (X direction), and the gate semiconductor layer 160 may protrude from the side surface 152_S of the second gate electrode 152 in the first direction (X direction). In this case, the first gate electrode 151 may protrude from the side surface 160_S of the gate semiconductor layer 160 in the first direction (X direction).

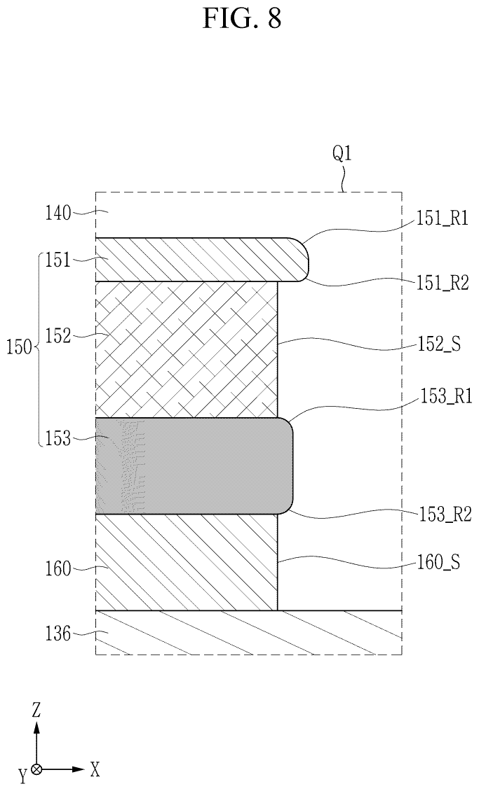

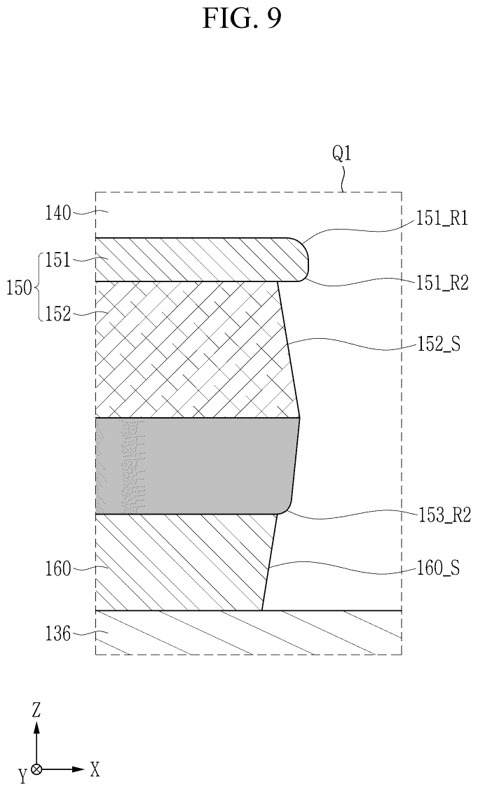

Referring to FIG. 8 and FIG. 9, the gate structure 150 of the semiconductor device according to some embodiments may further include a third gate electrode 153 disposed between the second gate electrode 152 and the gate semiconductor layer 160.

In some embodiments, at least one of the first to third gate electrodes 151, 152, and 153 may protrude from the side surface 160_S of the gate semiconductor layer 160 in the first direction (X direction). For example, as shown in FIG. 8, the third gate electrode 153 and the first gate electrode 151 may protrude from the side surface 160 S of the gate semiconductor layer 160 in the first direction (X direction), and the side surface 152_S of the second gate electrode 152 may be aligned with (or collinear with) the side surface 160_S of the gate semiconductor layer 160. As another example, as shown in FIG. 9, the first to third gate electrodes 151, 152, and 153 may protrude from the side surface 160_S of the gate semiconductor layer 160 in the first direction (X direction).

In the examples shown in FIGS. 8 and 9, at least one of the first gate electrode 151 to the third gate electrode 153 may have a different width from the others. For example, the width of the third gate electrode 153 in the first direction (X direction) may be smaller than that of the first gate electrode 151 in the first direction (X direction), but the invention is not limited thereto.

In some embodiments, as shown in FIG. 8, the third gate electrode 153 may include a third curved surface 153_R1 between the upper surface and the side surface of the third gate electrode 153 and a fourth curved surface 153_R2 between the lower surface and the side surface thereof. The third curved surface 153_R1 of the third gate electrode 153 and the fourth curved surface 153_R2 of the third gate electrode 153 may have curved surfaces. In this case, the curvature of the third curved surface 153_R1 of the third gate electrode 153 may be smaller than that of the fourth curved surface 153_R2 of the third gate electrode 153. However, the present invention is not limited thereto, and for example, the third curved surface 153_R1 of the third gate electrode 153 and the fourth curved surface 153_R2 of the third gate electrode 153 may include at least one inclined surface therebetween. For example, the side surface of the third gate electrode 153 may include multiple inclined surfaces with different inclinations. Alternatively, as shown in FIG. 9, the third gate electrode 153 may not include the third curved surface between the upper surface and the side surface thereof.

The third gate electrode 153 may include a conductive material. The third gate electrode 153 may include a material different from that of the second gate electrode 152, but the invention is not limited thereto. The third gate electrode 153 may include a material having an etching rate (etched amount of the material per unit time with respect to a certain etching process) different from that of the first gate electrode 151 and/or the second gate electrode 152. For example, the third gate electrode 153 may include a metal, a metal alloy, a conductive metal nitride, a metal silicide, a doped semiconductor material, a conductive metal oxide, a conductive metal oxynitride, or the like.

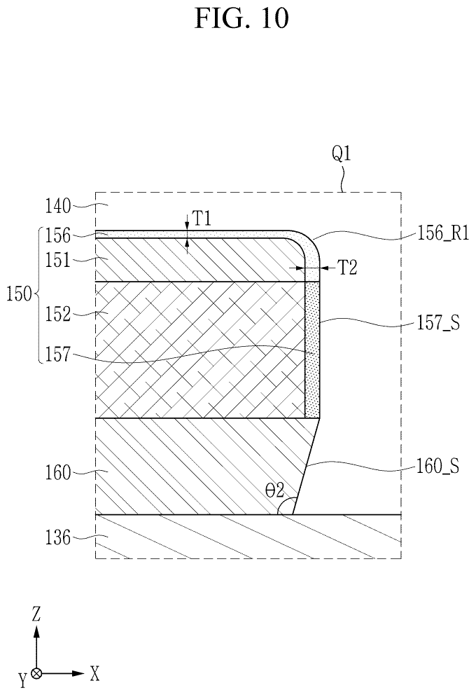

Referring to FIG. 10 to FIG. 12, the gate structure 150 of the semiconductor device according to some embodiments may further include a first gate barrier layer 156 disposed on the upper surface and the side surface of the first gate electrode 151 and a second gate barrier layer 157 disposed on the side surface of the second gate electrode 152.

The first gate barrier layer 156 may surround the first gate electrode 151. The first gate barrier layer 156 may be disposed on the upper and side surfaces of the first gate electrode 151. The first gate barrier layer 156 may be conformally disposed on the upper and side surfaces of the first gate electrode 151. In some embodiments, the first gate barrier layer 156 may include a first portion disposed on the upper surface of the first gate electrode 151 and a second portion disposed on the side surface of the first gate electrode 151. In this case, the first thickness T1 of the first portion of the first gate electrode 151 may be smaller than the second thickness T2 of the second portion of the first gate electrode 151. This may be due to process characteristics in which at least a portion of the first gate barrier layer 156 disposed on the upper surface of the first gate electrode 151 is removed together, in the process of forming the gate semiconductor layer 160 by patterning the gate semiconductor material layer (160a in FIG. 29) after forming the first gate barrier layer 156. The thickness of a layer may refer to the dimension in the direction perpendicular to the surface of the layer. The direction perpendicular to the surface may refer to its average orientation and not include minor unintentional deviations (e.g., pits) that may be formed during a manufacturing process.

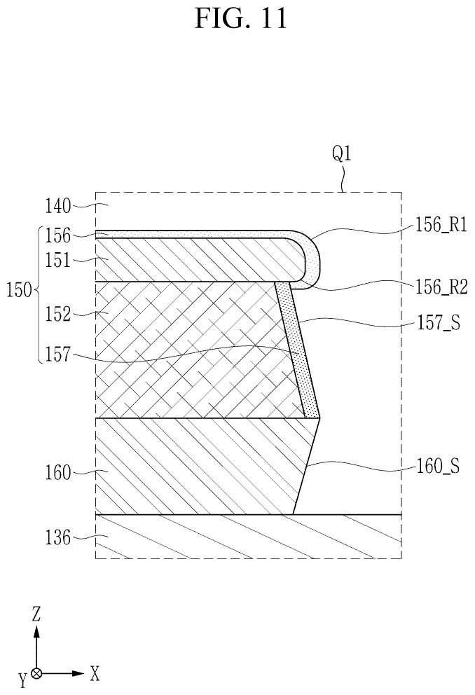

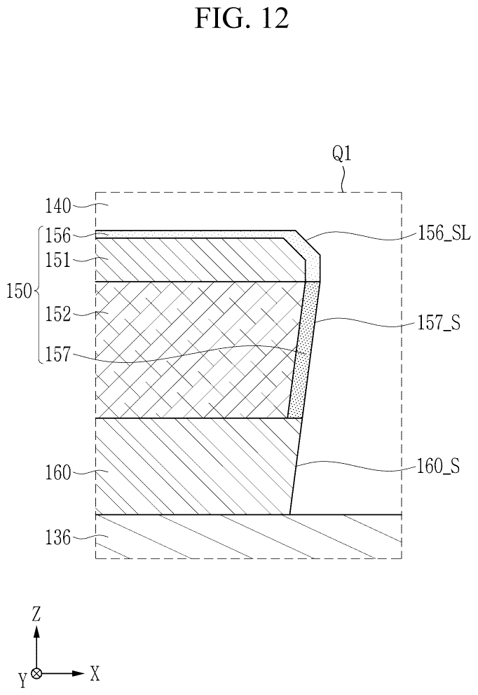

In some embodiments, the side surface of the first gate barrier layer 156 may include a curved surface. For example, as shown in FIG. 10, the first gate barrier layer 156 may include a fifth curved surface 156_R1 between the upper surface and the side surface of the first gate barrier layer 156. As another example, as shown in FIG. 11, the first gate barrier layer 156 may include two curved surfaces. For example, a fifth curved surface 156_R1 is formed between the upper surface and the side surface of the first gate barrier layer 156, and a sixth curved surface 156_R2 is formed between the lower surface and the side surface thereof. In this case, the curvature of the fifth curved surface 156_R1 of the first gate barrier layer 156 may be smaller than that of the sixth curved surface 156_R2 of the first gate barrier layer 156. For example, as shown in FIG. 12, the first gate barrier layer 156 may include an inclined surface 156_SL between the upper surface and the side surface thereof. However, the invention is not limited thereto, and the side surface of the first gate barrier layer 156 may include a plurality of inclined surfaces. For example, the first gate barrier layer 156 may have a side surface comprising multiple inclined surfaces. An angle between the inclined surface 156_SL of the first gate barrier layer 156 and the upper surface of the channel layer 132 may be an acute angle. This may be due to process characteristics in which at least a portion of the first gate barrier layer 156 is removed together in the process of patterning the gate semiconductor layer 160 as described later.

The first gate barrier layer 156 may include an oxide film or a nitride film. For example, the first gate barrier layer 156 may include a metal nitride, a metal oxide, or a metal oxynitride. The material included in the first gate barrier layer 156 may be a conductive material. The first gate barrier layer 156 may include the same element as the material configuring the first gate electrode 151. For example, the first gate barrier layer 156 and the first gate electrode 151 may include a first material and a second material different from the first material, and the content of the first material of the first gate electrode 151 may be smaller than the content of the first material of the first gate barrier layer 156. For example, the first gate barrier layer 156 may include the second material at a first atomic percent, the first gate electrode may comprise the second material at a second atomic percent, and the second atomic percent may be greater than the atomic percent. In this case, the first material may include titanium (Ti), tantalum (Ta), aluminum (Al), or a combination thereof, and the second material may include nitrogen (N) or oxygen (O). This may be due to process characteristics in which the first gate barrier layer 156 is formed on the upper and side surfaces of the exposed first gate electrode 151 by forming a gate semiconductor material layer (160a in FIG. 29) using an etching gas (EG of FIG. 30) containing nitrogen (N) or oxygen (O).

The second gate barrier layer 157 may surround the side surface of the second gate electrode 152. The second gate barrier layer 157 may be conformally disposed on the side surface of the second gate electrode 152. The second gate barrier layer 157 may be in contact with the first gate barrier layer 156. At least a portion of the gate semiconductor layer 160 may be in contact with the second gate barrier layer 157. The second gate barrier layer 157 may be disposed between the first gate barrier layer 156 and the gate semiconductor layer 160, but the invention is not limited thereto. The side surface 157_S of the second gate barrier layer 157 may have various inclined surfaces, but the invention is not limited thereto, and may include a curved surface. The thickness of the second gate barrier layer 157 in a horizontal direction (e.g., X-direction) may be greater than the first thickness T1 of the first portion of the first gate barrier layer 156.

The second gate barrier layer 157 may include an oxide film or a nitride film. For example, the second gate barrier layer 157 may include a metal nitride, a metal oxide, or a metal oxynitride. The material included in the second gate barrier layer 157 may be a conductive material. The second gate barrier layer 157 may include the same element as the material configuring the second gate electrode 152. For example, the second gate barrier layer 157 and the second gate electrode 152 may include a first material and a second material different from the first material, and the content of the first material of the second gate electrode 152 may be smaller than the content of the first material of the second gate barrier layer 157. For example, the second gate barrier layer 157 may include the second material at a first atomic percent, the second gate electrode may comprise the second material at a second atomic percent, and the second atomic percent may be greater than the atomic percent. In this case, the first material may include titanium (Ti), tantalum (Ta), aluminum (Al), or a combination thereof, and the second material may include nitrogen (N) or oxygen (O). This may be due to process characteristics in which the second gate barrier layer 157 is formed on the side surface of the exposed second gate electrode 152 by forming the gate semiconductor material layer (160a in FIG. 29) using the etching gas (EG of FIG. 30) containing nitrogen (N) or oxygen (O).

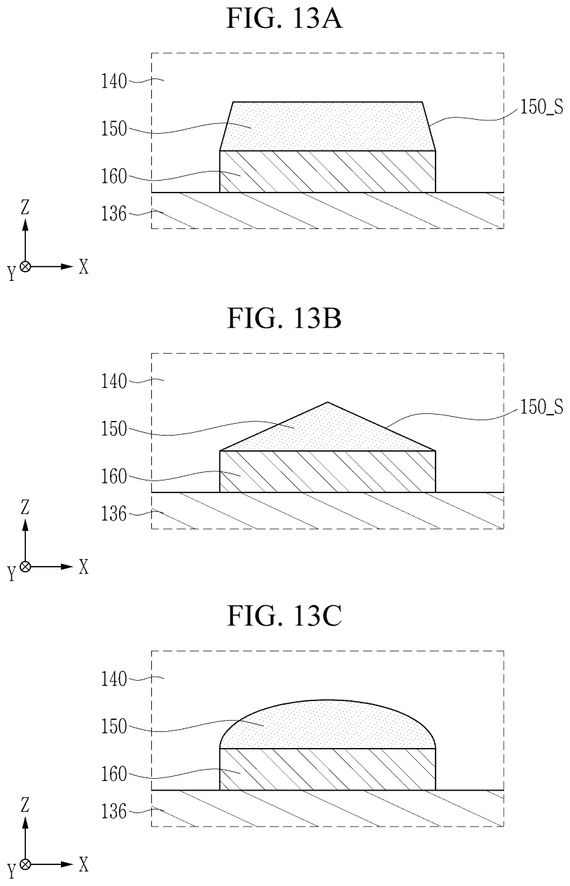

Hereinafter, a semiconductor device according to some embodiments will be described with further reference to FIG. 13A to FIG. 13C.

FIG. 13A to FIG. 13C illustrate cross-sectional views of portions of semiconductor devices according to some embodiments. FIG. 13A to FIG. 13C illustrate enlarged cross-sectional views of the gate structure 150 and the gate semiconductor layer 160 of semiconductor devices according to some embodiments. For better understanding and ease of description, the barrier layer 136, the gate semiconductor layer 160, the gate structure 150, and the passivation layer 140 of the semiconductor device according to some embodiments are illustrated in FIG. 13A to FIG. 13C, while the substrate 110, the seed layer 121, the buffer layer 120, the channel layer 132, the source electrode 173, and the drain electrode 175 are not illustrated.

Referring to FIG. 13A to FIG. 13C, the gate structure 150 of the semiconductor device according to some embodiments may be a single layer. The gate structure 150 may be disposed on the upper surface of the gate semiconductor layer 160. The gate structure 150 may cover the upper surface of the gate semiconductor layer 160.

In some embodiments, the gate structure 150 may have various shapes. For example, as shown in FIG. 13A, in a cross-sectional view, the gate structure 150 may have a trapezoidal shape. The side surface 150_S of the gate structure 150 may have an inclination angle with respect to the upper surface of the barrier layer 136. In this case, the inclination angle of the side surface 150_S of the gate structure 150 may be an acute angle. For example, the gate structure 150 may have a tapered shape. The width of the gate structure 150 may gradually decrease as the distance from the upper surface of the barrier layer 136 increases along the first direction (X direction). As another example, as shown in FIG. 13B, in a cross-sectional view, the gate structure 150 may have a triangular shape. As another example, as shown in FIG. 13C, in a cross-sectional view, the gate structure 150 may have a semicircular shape. For example, the side surface and the upper surface of the gate structure 150 may be curved. However, the present invention is not limited thereto, and the side surface of the gate structure 150 may further include at least one inclined surface. For example, the side surface of the gate structure 150 may include multiple inclined surfaces with different inclinations.

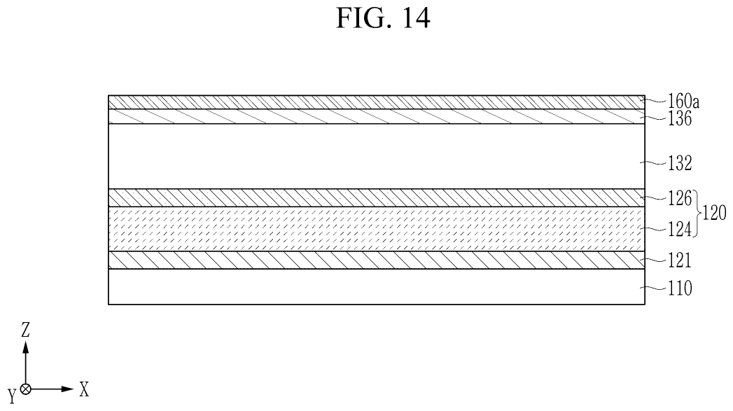

Hereinafter, a manufacturing method of a semiconductor device according to an embodiment will be described with reference to FIG. 14 to FIG. 23.

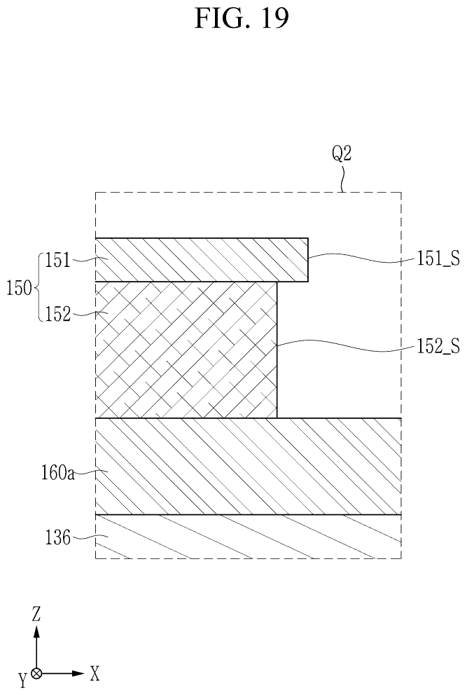

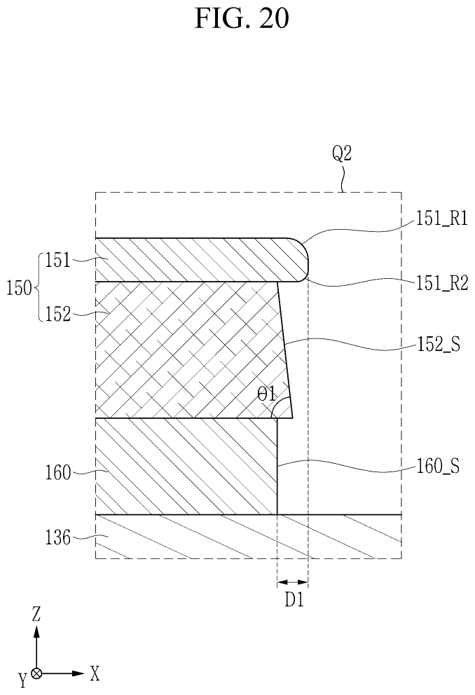

FIG. 14 to FIG. 18 and FIG. 21 to FIG. 23 illustrate cross-sectional views of a process sequence to form a semiconductor device according to an embodiment. FIG. 19 is an enlarged cross-sectional view of region Q2 of FIG. 18. FIG. 20 is an enlarged cross-sectional view illustrating a subsequent step to the process step described with FIG. 19. FIG. 20 is a corresponding enlarged cross-sectional view to FIG. 19.

As shown in FIG. 14, first, the seed layer 121 and the buffer layer 120 may be sequentially formed on the substrate 110. In the embodiment, the buffer layer 120 may include the superlattice layer 124 and the high resistance layer 126.

The substrate 110 may include a semiconductor material. For example, the substrate 110 may include sapphire, Si, SiC, AlN, GaN, or a combination thereof. The substrate 110 may be a silicon on insulator (SOI) substrate. However, the invention is not limited thereto, and all generally used substrates may be applied.

The seed layer 121 and the superlattice layer 124 may be sequentially formed using an epitaxial growth method. The seed layer 121 and the superlattice layer 124 may be made of the same semiconductor material. However, the material composition ratios of respective layers may be different in consideration of the role of respective layers and the performance required for the semiconductor device. The seed layer 121 and the superlattice layer 124 may include one or more materials selected from Group III-V materials, for example, nitrides including Al, Ga, In, B, or a combination thereof. The seed layer 121 and the superlattice layer 124 may be AlxInyGa4-x-yN(0≤x≤1, 0≤y≤1, x+y≤1). For example, the seed layer 121 and the superlattice layer 124 may include AIN, GaN, InN, InGaN, AlGaN, AlInN, AlInGaN, or a combination thereof.

In the embodiment, the superlattice layer 124 may be formed of multiple layers in which layers containing different materials are alternately stacked. For example, the superlattice layer 124 may have a structure in which a layer made of AlGaN and a layer made of AIN are repeatedly stacked. For example, AlGaN/AlN/AlGaN/AlGaN/AlGaN/AlN may be sequentially stacked to form the superlattice layer 124.

The high resistance layer 126 may be made of a material with low-conductivity to electrically insulate the substrate 110 and the channel layer 132. The high-resistance layer may include one or more materials selected from Group III-V materials, for example, nitrides including Al, Ga, In, B, or a combination thereof. The high resistance layer 126 may be AlxInyGa1-x-yN(0≤x≤1, 0≤y≤1, x+y≤1). For example, the high resistance layer 126 may include AlN, GaN, InN, InGaN, AlGaN, AlInN, AlInGaN, or a combination thereof. The high resistance layer 126 may be a single layer or a multilayer.

Subsequently, the channel layer 132 and the barrier layer 136 may be sequentially formed on the high resistance layer 126.

In the embodiment, the channel layer 132 and the barrier layer 136 may be sequentially formed using an epitaxial growth method. For example, the channel layer 132 may be formed on the high resistance layer 126, and the barrier layer 136 may be formed on the channel layer 132.

The channel layer 132 and the barrier layer 136 may be made of the same-based semiconductor material. However, the material composition ratios of respective layers may be different in consideration of the role of respective layers and the performance required for the semiconductor device. The channel layer 132 and the barrier layer 136 may include one or more materials selected from Group III-V materials, for example, nitrides including Al, Ga, In, B, or a combination thereof. The channel layer 132 and the barrier layer 136 may be AlxInyGa1-x-yN(0≤x≤1, 0≤y≤1, x+y≤1). For example, the channel layer 132 and the barrier layer 136 may include AlN, GaN, InN, InGaN, AlGaN, AlInN, AlInGaN, or a combination thereof. The barrier layer 136 may include a material having an energy band gap different from that of the channel layer 132. The barrier layer 136 may have a higher energy band gap than the channel layer 132.

As an example, the substrate 110 may include Si, the seed layer 121 may include AIN, and the superlattice layer 124 may include AlGaN and AlN. The high resistance layer 126 may include GaN, the channel layer 132 may include GaN, and the barrier layer 136 may include AlGaN. The channel layer 132 and the barrier layer 136 may or may not be doped with impurities (not including a substantial number of impurities).

As the lattice structure of Si and the lattice structure of GaN are different, it may not be easy to grow the channel layer 132 made of GaN directly on the substrate 110 made of Si. In the manufacturing method of the semiconductor device according to the embodiment, the lattice structure of the channel layer 132 may be stably formed by first forming the seed layer 121, the superlattice layer 124, and the high resistance layer 126 on the substrate 110 and then forming the channel layer 132.

Next, the gate semiconductor material layer 160a may be formed on the barrier layer 136.

The gate semiconductor material layer 160a may be formed using an epitaxial growth method. The gate semiconductor material layer 160a may be made of the same-based semiconductor material as the channel layer 132 and the barrier layer 136. However, the material composition ratios of respective layers may be different in consideration of the role of respective layers and the performance required for the semiconductor device. The gate semiconductor material layer 160a may include a material having an energy band gap different from that of the barrier layer 136. For example, the gate semiconductor material layer 160a may include GaN, and may be doped with impurities. The gate semiconductor material layer 160a may be doped with p-type impurities, for example, magnesium (Mg). For example, the gate semiconductor material layer 160a may include a p-type semiconductor material (e.g., p-type GaN).

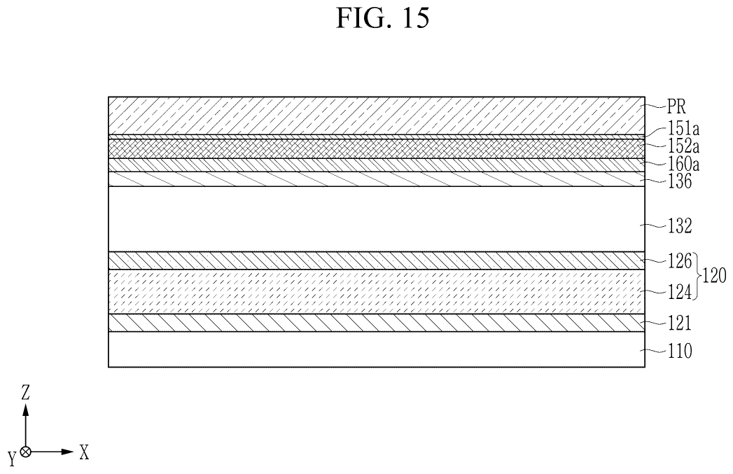

As shown in FIG. 15, the gate electrode material layers 151a and 152a may be formed on the gate semiconductor material layer 160a, and a photoresist PR may be formed on the gate electrode material layers 151a and 152a.

The gate electrode material layers 151a and 152a may be formed using a deposition process. For example, the gate electrode material layers 151a and 152a may be formed using at least one of electron beam (E-beam) evaporation, sputtering, physical vapor deposition (PVD), thermal chemical vapor deposition (thermal CVD), low pressure chemical vapor deposition (LP-CVD), plasma-enhanced chemical vapor deposition (PE-CVD), and atomic layer deposition (ALD) technologies, but the invention is not limited thereto.

The gate electrode material layers 151a and 152a may include a conductive material. For example, the gate electrode material layers 151a and 152a may include a metal, a metal alloy, a conductive metal nitride, a metal silicide, a doped semiconductor material, a conductive metal oxide, a conductive metal oxynitride, or the like. For example, the gate electrode material layers 151a and 152a may include, for example, at least one of a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride (TiAlN), a tantalum aluminum nitride (TaAlN), a tungsten nitride (WN), ruthenium (Ru), a titanium aluminum (TiAl), a titanium aluminum carbonitride (TiAlC-N), a titanium aluminum carbide (TiAlC), a titanium carbide (TiC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and a combination thereof, but the invention is not limited thereto. The gate electrode material layers 151a and 152a may be formed as a single layer or a multilayer.

Subsequently, a photoresist PR may be formed on the upper surfaces of the gate electrode material layers 151a and 152a. The photoresist PR may be directly disposed on the gate electrode material layers 151a and 152a.

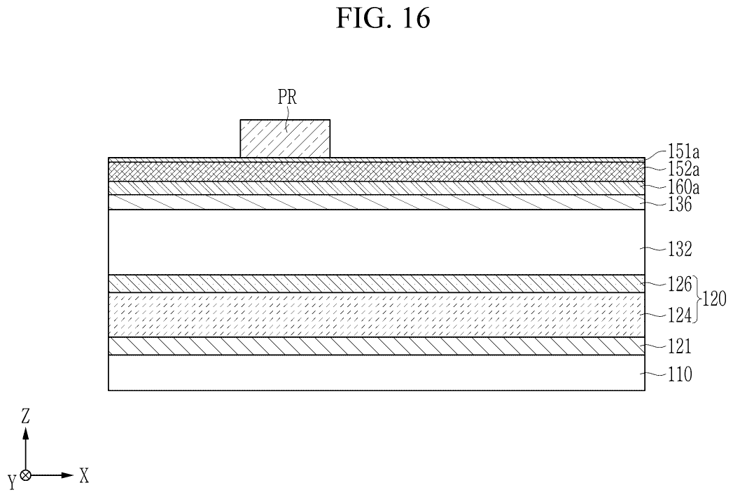

As shown in FIG. 16, the photoresist PR may be patterned using a photo process.

As shown in FIG. 17, the gate electrode 151 and the second gate electrode 152 may be formed by patterning the gate electrode material layers 151a and 152a using the photoresist PR as a mask.

For example, the gate electrode material layers 151a and 152a may be patterned using the photoresist PR as a mask. Accordingly, the remaining portion of the first gate electrode material layer 151a may be the first gate electrode 151, and the remaining portion of the second gate electrode material layer 152a may be the second gate electrode 152.

In this case, the first gate electrode material layer 151a and the second gate electrode material layer 152a may have different etching rates with respect to an etch gas or an etchant for etching the gate electrode material layers 151a and 152a. Accordingly, even when the gate electrode material layers 151a and 152a are etched together using the same mask, the degree to which the first gate electrode 151 and the second gate electrode 152 are etched may be different. Accordingly, the width of the first gate electrode 151 in the first direction (X direction) may be different from that of the second gate electrode 152 in the first direction (X direction). For example, the width of the first gate electrode 151 in the first direction (X direction) may be greater than that of the second gate electrode 152 in the first direction (X direction), but the invention is not limited thereto.

As shown in FIG. 18 and FIG. 19, the photoresist PR may be removed. Accordingly, the upper surface of the first gate electrode 151 may be exposed. For example, the upper surface and the side surface 151_S of the first gate electrode 151 and the side surface 152_S of the second gate electrode 152 may be exposed. In the embodiment, as described above, the width of the first gate electrode 151 in the first direction (X direction) may be greater than that of the second gate electrode 152 in the first direction (X direction). For example, the side surface 151_S of the first gate electrode 151 may protrude in the first direction (X direction) than (beyond) the side surface 152_S of the second gate electrode 152.

As shown in FIG. 20, the gate semiconductor material layer 160a may be patterned using the gate structure 150 as a mask. As the gate semiconductor material layer 160a is patterned, at least a portion of the barrier layer 136, which is disposed below the removed portion of the gate semiconductor material layer 160a, may be exposed. Accordingly, the remaining portion of the gate semiconductor material layer 160a may be the gate semiconductor layer 160.

The gate semiconductor layer 160 may be covered by the gate structure 150. The width of the gate semiconductor layer 160 in the first direction (X direction) may be smaller than that of the gate structure 150 in the first direction (X direction). For example, the width of the gate semiconductor layer 160 in the first direction (X direction) may be smaller than that of the first gate electrode 151 and/or the second gate electrode 152 in the first direction (X direction). Here, the width of the gate semiconductor layer 160 in the first direction (X direction) may mean a maximum width of the gate semiconductor layer 160 in the first direction (X direction), and the width of the gate structure 150 in the first direction (X direction) may mean a maximum width of the gate structure 150 in the first direction (X direction). In addition, each of the first gate electrode 151 and the second gate electrode 152 may protrude from the side surface 160_S of the gate semiconductor layer 160 in the first direction (X direction). Accordingly, when the electric field is concentrated around the gate semiconductor layer 160, the electric field may be effectively dispersed by the gate structure 150. However, the present invention is not limited thereto, and as in the embodiment of FIG. 7, the second gate electrode 152 may not protrude from the side surface 160_S of the gate semiconductor layer 160 in the first direction (X direction).

In this case, at least a portion of the gate structure 150 may be removed together. For example, a portion of the edge of the first gate electrode 151 may be removed together during the patterning of the gate semiconductor material layer 160a. For example, an upper edge and a lower edge of the first gate electrode 151 may be etched to form a first curved surface 151_R1 between the upper surface and the side surface of the first gate electrode 151, and to form a second curved surface 151_R2 between the lower surface and the side surface thereof. In addition, a portion of the edge of the second gate electrode 152 is removed together, so that the side surface 152_S of the second gate electrode 152 may be formed to have a first inclination angle θ1 with respect to the upper surface of the channel layer 132.

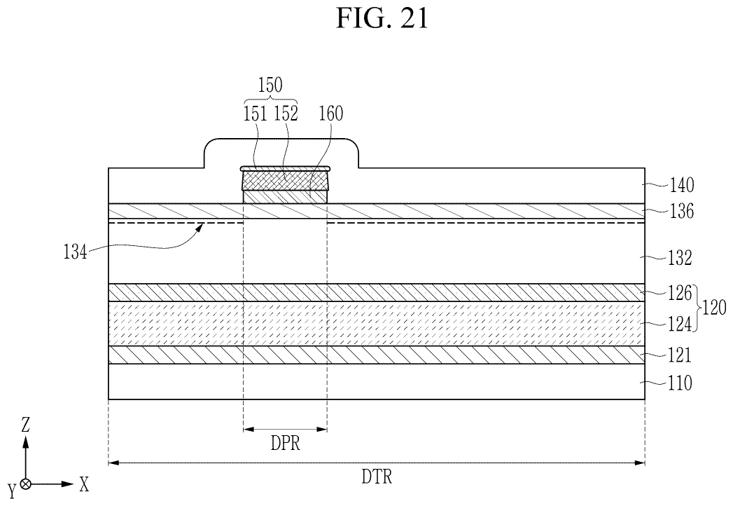

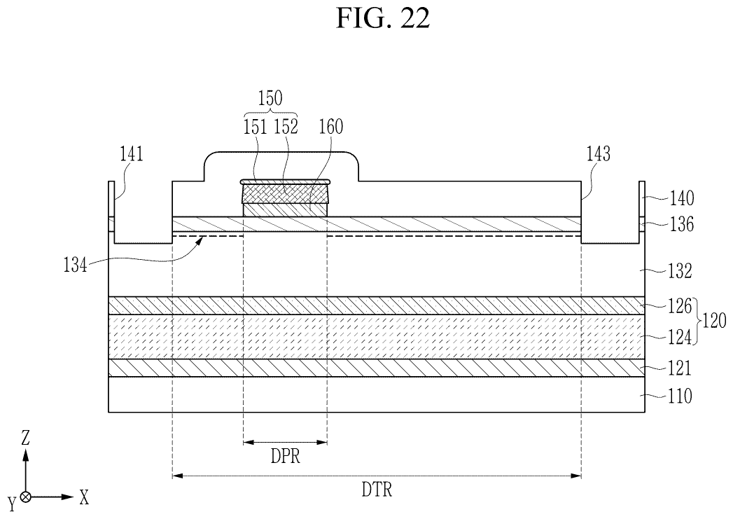

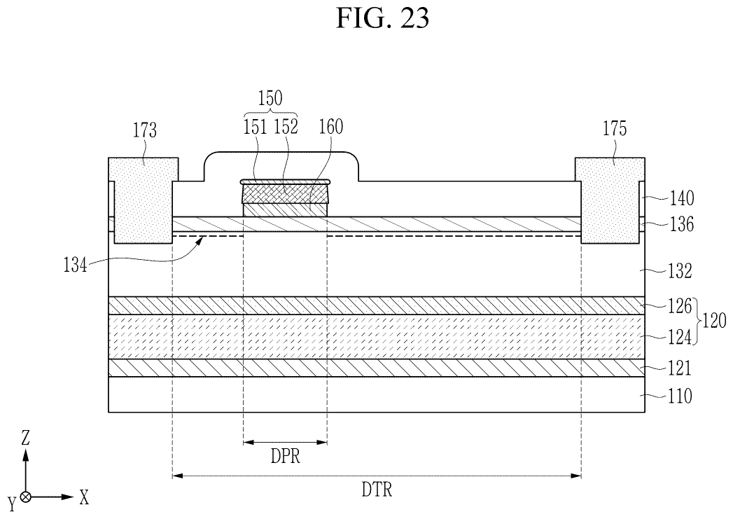

As shown in FIG. 21, the passivation layer 140 may be formed on the barrier layer 136 and the gate structure 150. For example, the passivation layer 140 may be formed to cover the barrier layer 136 and the gate structure 150. The passivation layer 140 may include an insulating material. For example, the passivation layer 140 may include an oxide such as SiO2 or A12O3. As another example, the passivation layer 140 may include a nitride such as SiN or an oxynitride such as SiON.

As shown in FIG. 22, the first trench 141 and the second trench 143 may be formed by patterning the passivation layer 140 using a photo process and an etching process. In this case, not only the passivation layer 140 but also the barrier layer 136 and the channel layer 132 may be patterned together.

For example, a photoresist pattern may be formed on the passivation layer 140, and the passivation layer 140, the barrier layer 136, and the channel layer 132 may be sequentially etched using the photoresist pattern as a mask. In this case, the passivation layer 140 and the barrier layer 136 may be penetrated by the first trench 141 and the second trench 143, and the upper surface of the channel layer 132 may be partially removed and recessed. The channel layer 132 may not be penetrated by the first trench 141 or the second trench 143.

In this case, the depth at which the upper surface of the channel layer 132 is recessed may be much smaller than the entire thickness of the channel layer 132. In addition, the depth at which the upper surface of the channel layer 132 is recessed may be smaller than the thickness of the barrier layer 136. However, the invention is not limited thereto, and the depth at which the upper surface of the channel layer 132 is recessed may be variously changed.

By the first trench 141 and the second trench 143, the side surfaces of the passivation layer 140 and the barrier layer 136 may be exposed to the outside and the upper and side surfaces of the channel layer 132 may be exposed to the first trench 141 or the second trench 143. The channel layer 132 may form bottom surfaces and sidewalls of the first trench 141 and the second trench 143, and the barrier layer 136 may form sidewalls of the first trench 141 and the second trench 143. The channel layer 132 may be exposed to the bottom surfaces and sidewalls of the first trench 141 and the second trench 143. The barrier layer 136 may be exposed to the sidewalls of the first trench 141 and the second trench 143.

The first trench 141 and the second trench 143 may be spaced apart from each other. The first trench 141 and the second trench 143 may be disposed on both sides of the gate structure 150. The first trench 141 may be disposed at one side of the gate structure 150 to be spaced apart from the gate structure 150. The second trench 143 may be disposed at the other side of the gate structure 150 to be spaced apart from the gate structure 150. The distance between the first trench 141 and the gate structure 150 may be smaller than that between the second trench 143 and the gate structure 150. Although the first trench 141 and the second trench 143 are illustrated to have similar shapes in width and depth, the present invention is not limited thereto. The shapes of the first trench 141 and the second trench 143 may be variously changed.

As shown in FIG. 23, a conductive material may be deposited in the first trench 141 and the second trench 143 and patterned to form the source electrode 173 and the drain electrode 175. Accordingly, the semiconductor device according to the embodiment may be formed.

In the embodiment, the source electrode 173 may be formed to fill the inside of the first trench 141. In the first trench 141, the source electrode 173 may be in contact with the channel layer 132 and the barrier layer 136. The source electrode 173 may be in contact with the side surfaces of the channel layer 132 and the barrier layer 136. The source electrode 173 may cover the side surfaces of the channel layer 132 and the barrier layer 136. The source electrode 173 may cover the recessed portion of the channel layer 132. The source electrode 173 may be electrically connected to the channel layer 132 through the first trench 141. The upper surface of the source electrode 173 may protrude from the upper surface of the passivation layer 140.

The drain electrode 175 may be formed to fill the inside of the second trench 143. In the second trench 143, the drain electrode 175 may be in contact with the channel layer 132 and the barrier layer 136. The drain electrode 175 may be in contact with the side surfaces of the channel layer 132 and the barrier layer 136. The drain electrode 175 may cover the side surfaces of the channel layer 132 and the barrier layer 136. The drain electrode 175 may be electrically connected to the channel layer 132 through the second trench 143. The upper surface of the drain electrode 175 may protrude from the upper surface of the passivation layer 140.

The source electrode 173 and the drain electrode 175 may be in ohmic contact with the channel layer 132. A region in contact with the source electrode 173 and the drain electrode 175 in the channel layer 132 may be doped at a relatively high concentration compared to other regions. For example, the channel layer 132 may be doped by an ion implant process, an annealing process, or the like. However, the invention is not limited thereto, and the doping process of the channel layer 132 may be performed by various other processes. The doping process of the channel layer 132 may be performed before forming the source electrode 173 and the drain electrode 175. In some cases, the channel layer 132 may not be doped (not including a substantial number of impurities).

The 2-dimensional electron gas 134 may be formed (or induced) in a portion adjacent to the barrier layer 136 inside the channel layer 132 between the source electrode 173 and the drain electrode 175. The 2-dimensional electron gas 134 may be disposed at the interface between the channel layer 132 and the barrier layer 136. The 2-dimensional electron gas 134 may be disposed in the drift region DTR between the source electrode 173 and the drain electrode 175. The depletion region DPR may be formed in the channel layer 132 by the gate semiconductor layer 160 having an energy band gap different from that of the barrier layer 136. The depletion region DPR may be provided in a portion of the channel layer 132, on which the gate semiconductor layer 160 is disposed. The gate semiconductor layer 160 may have an energy band gap different from that of the barrier layer 136 such that, in a normal state, the 2-dimensional electron gas 134 is not induced in the depletion region DPR. Accordingly, the semiconductor device according to the embodiment may have a normally off characteristic. For example, the semiconductor device according to the embodiment may be a normally off high electron mobility transistor (HEMT). In the gate off state, the two-dimensional electron gas 134 may be disposed in the drift region DTR excluding the depletion region DPR of the channel layer 132. In the gate-on state, the 2-dimensional electron gas 134 may be induced continuously within the entire depletion region DPR, electrical current may flow between the source electrode 173 and the drain electrode 175.

In the embodiment, a field dispersion layer (not shown in the drawing) may be formed together in the forming of the source electrode 173 and the drain electrode 175. The field dispersion layer may be disposed between the source electrode 173 and the drain electrode 175. The field dispersion layer may overlap the gate structure 150 in the third direction (Z direction). The field dispersion layer may be electrically connected to the source electrode 173. The field dispersion layer may be integrally formed with the source electrode 173. The field dispersion layer may include the same material as the source electrode 173, and may be disposed on the same layer as the source electrode 173.

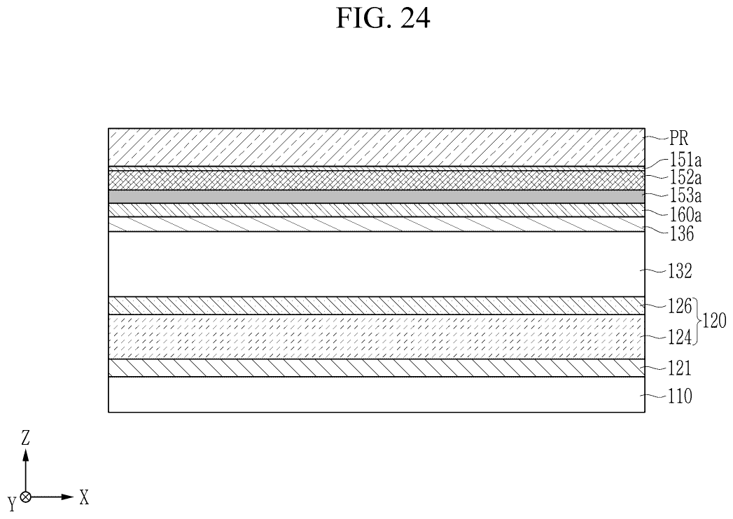

Hereinafter, a manufacturing method of a semiconductor device according to some embodiments will be described with reference to FIG. 24 to FIG. 28.

FIG. 24 to FIG. 28 illustrate process cross-sectional views of a process sequence of manufacturing a semiconductor device according to some embodiments. FIG. 24 to FIG. 28 are drawings for illustrating process steps of forming the gate structure of the semiconductor device according to the embodiment of FIG. 8 and FIG. 9. The embodiment illustrated in FIG. 24 to FIG. 28 has substantially the same as the embodiment illustrated in FIG. 14 to FIG. 23 except for the process steps of forming the gate structure, so a duplicated description thereof may be omitted and differences between the embodiments may be mainly described. The embodiment illustrated in FIG. 24 to FIG. 28 may be partially different from the previous embodiment such that a third gate electrode is further formed.

As illustrated in FIG. 24, gate electrode material layers 151a, 152a, and 153a may be formed on the gate semiconductor material layer 160a, and a photoresist PR may be formed on the gate electrode material layers 151a, 152a, and 153a.

The gate electrode material layers 151a, 152a, and 153a may be formed using a deposition process. For example, the gate electrode material layers 151a, 152a, and 153a may be formed using at least one of electron beam deposition, sputtering, physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD) techniques, but the invention is not limited thereto.

The gate electrode material layers 151a, 152a, and 153a may include a conductive material. For example, the gate electrode material layers 151a, 152a, and 153a may include a metal, a metal alloy, a conductive metal nitride, a metal silicide, a doped semiconductor material, a conductive metal oxide, a conductive metal oxynitride, or the like. In this case, the first gate electrode material layer 151a, the second gate electrode material layer 152a, and the third gate electrode material layer 153a may have different etching rates with respect to an etch gas or an etchant for etching the gate electrode material layers 151a, 152a, and 153a.

Subsequently, a photoresist PR may be formed on the upper surfaces of the gate electrode material layers 151a, 152a, and 153a. The photoresist PR may be disposed directly on the gate electrode material layers 151a, 152a, and 153a.

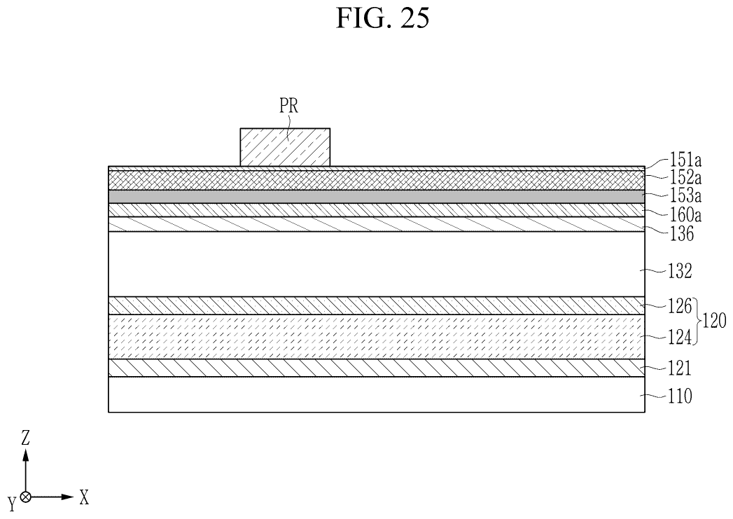

As shown in FIG. 25, the photoresist PR may be patterned using a photo process.

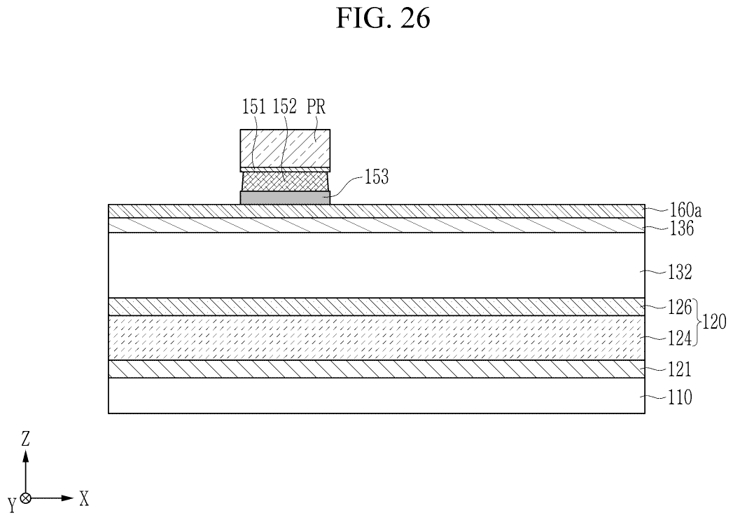

As shown in FIG. 26, the first gate electrode 151, the second gate electrode 152, and the third gate electrode 153 may be formed by patterning the gate electrode material layers 151a, 152a, and 153a using the photoresist PR as a mask.

For example, the gate electrode material layers 151a, 152a, and 153a may be patterned using the photoresist PR as a mask. Accordingly, the remaining portion of the first gate electrode material layer 151a may be the first gate electrode 151, the remaining portion of the second gate electrode material layer 152a may be the second gate electrode 152, and the remaining portion of the third gate electrode material layer 153a may be the third gate electrode 153.

In this case, since the first gate electrode material layer 151a, the second gate electrode material layer 152a, and the third gate electrode material layer 153a may have different etching rates with respect to the etching gas or the etching solution for etching the gate electrode material layers 151a, 152a, and 153a, even when the gate electrode material layers 151a, 152a, and 153a are etched together using the same mask, the degree to which the first gate electrode 151, the second gate electrode 152, and the third gate electrode 153 are etched may be different. Accordingly, at least one of the first gate electrode 151 to the third gate electrode 153 may have a different width. For example, the width of the third gate electrode 153 in the first direction (X direction) may be smaller than that of the first gate electrode 151 in the first direction (X direction), but the invention is not limited thereto.

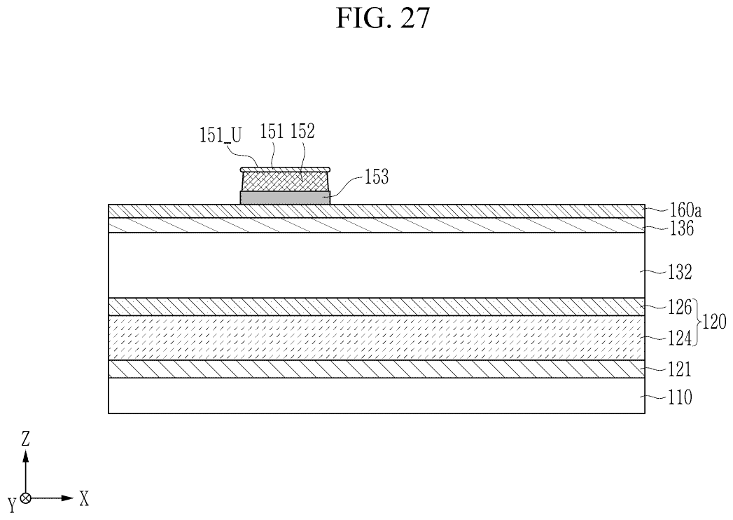

As shown in FIG. 27, the photoresist PR may be removed. Accordingly, the upper surface 151_U of the first gate electrode 151 may be exposed. For example, the upper surface 151_U and the side surface of the first gate electrode 151 and the side surface of the second gate electrode 152 may be exposed.

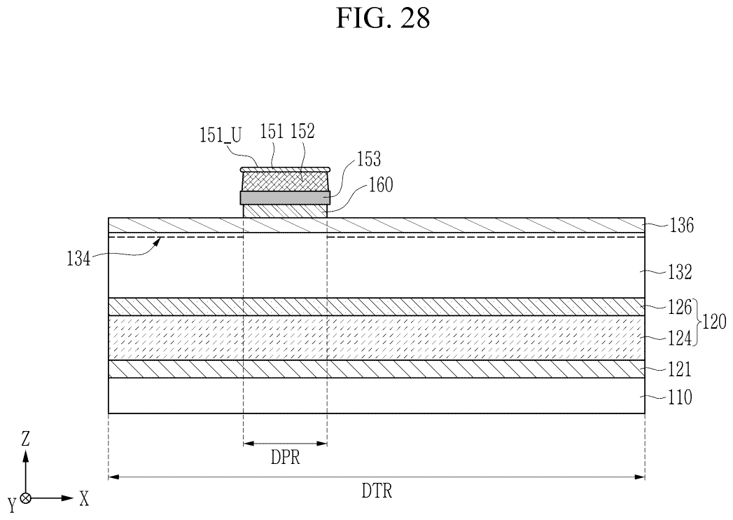

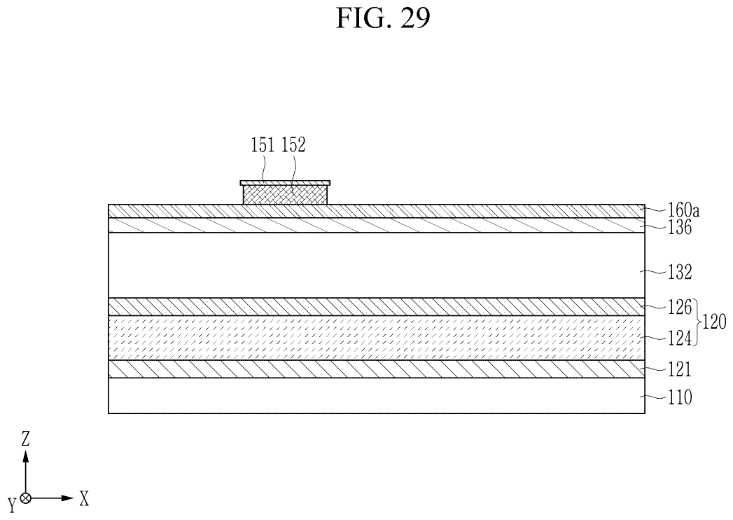

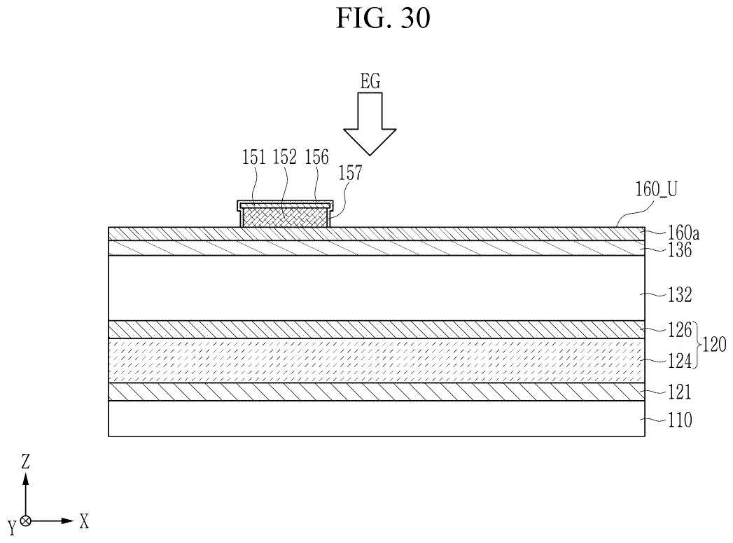

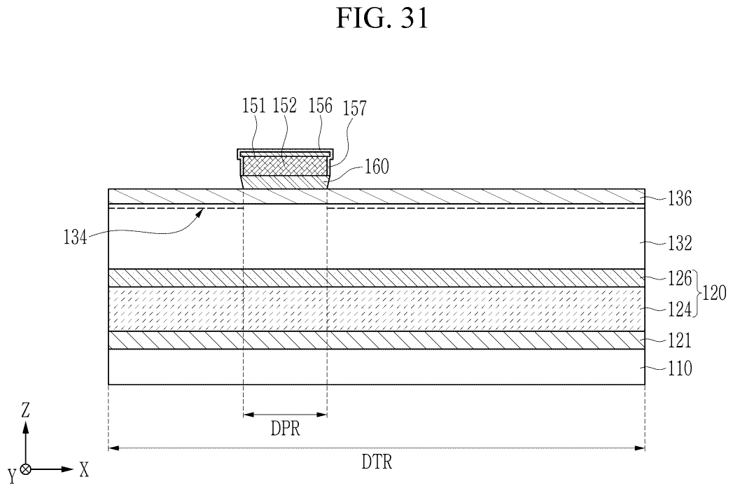

As shown in FIG. 28, the gate semiconductor material layer 160a may be patterned using the gate structure 150 as a mask. As the gate semiconductor material layer 160a is patterned, at least a portion of the barrier layer 136 disposed below the removed portion of the gate semiconductor material layer 160a may be exposed. Accordingly, the remaining portion of the gate semiconductor material layer 160a may be the gate semiconductor layer 160.

The gate semiconductor layer 160 may be covered by the gate structure 150. The width of the gate semiconductor layer 160 in the first direction (X direction) may be smaller than that of the gate structure 150 in the first direction (X direction). For example, the width of the gate semiconductor layer 160 in the first direction (X direction) may be smaller than that of the first gate electrode 151, the second gate electrode 152, and/or the third gate electrode 153 in the first direction (X direction). Here, the width of the gate semiconductor layer 160 in the first direction (X direction) may mean a maximum width of the gate semiconductor layer 160 in the first direction (X direction), and the width of the gate structure 150 in the first direction (X direction) may mean a maximum width of the gate structure 150 in the first direction (X direction). In addition, at least one of the first gate electrode 151, the second gate electrode 152, and the third gate electrode 153 may protrude from the side surface 160_S of the gate semiconductor layer 160 in the first direction (X direction). Accordingly, when the electric field is concentrated around the gate semiconductor layer 160, the electric field may be effectively dispersed by the gate structure 150.

In this case, at least a portion of the gate structure 150 may be removed together. For example, a portion of the edge of the third gate electrode 153 may be removed together during the patterning of the gate semiconductor material layer 160a. For example, an upper edge and a lower edge of the third gate electrode 153 may be etched to form a curved surface between the upper surface and the side surface of the third gate electrode 153 and/or a curved surface between the lower surface and the side surface thereof.

Subsequently, though not shown in the drawings, the passivation layer 140 may be formed on the barrier layer 136 and the gate structure 150. Trenches may be formed by patterning the passivation layer 140 using a photo and etching process, and the source electrode 173 and the drain electrode 175 may be formed by forming a conductive material within the trenches. Accordingly, the semiconductor device according to the embodiment of FIG. 8 and FIG. 9 may be formed.

Hereinafter, a manufacturing method of a semiconductor device according to some embodiments will be described with reference to FIG. 29 to FIG. 31.

FIG. 29 to FIG. 31 illustrate process cross-sectional views of a process sequence of manufacturing a semiconductor device according to some embodiments. FIG. 29 to FIG. 31 are drawings for illustrating process steps of forming the gate structure of the semiconductor device according to the embodiment of FIG. 10 to FIG. 12. The embodiment illustrated in FIG. 29 to FIG. 31 has substantially the same as the embodiment illustrated in FIG. 14 to FIG. 23 except for the process steps of forming the gate structure, so a duplicated description thereof may be omitted and differences between the embodiments may be mainly described. The embodiment illustrated in FIG. 29 to FIG. 31 may be partially different from the previous embodiment such that a gate barrier layer is further formed.

Referring to FIG. 29, after the gate electrode material layers 151a, and 152a are patterned using the photoresist as a mask to form the first gate electrode 151 and the second gate electrode 152. the photoresist may be removed.

As shown in FIG. 30 and FIG. 31, the gate semiconductor material layer 160a may be patterned using the gate structure (the first gate electrode 151 and the second gate electrode 152) as a mask.

The process of patterning the gate semiconductor material layer 160a may be performed using an etch gas EG for etching the gate semiconductor material layer 160a. In order to minimize damage to the barrier layer 136 in the process of etching the gate semiconductor material layer 160a, a selective etching process condition is required to have a difference in the etching rate of the gate semiconductor material layer 160a and the barrier layer 136. For example, the barrier layer 136 made of AlGaN may be hardly etched, while the gate semiconductor material layer 160a made of p-GaN may be easily etched. In this case, a surface oxidation (or nitridation) etching method may be used by adding a nitrogen (N) or oxygen (O) element to the etching gas EG. For example, the etching gas EG for etching the gate semiconductor material layer 160a according to the embodiment may include nitrogen (N) or oxygen (O). Accordingly, the exposed upper surface 160_U of the gate semiconductor material layer 160a may be oxidized (or nitrated) and easily etched. Since the barrier layer 136 is not damaged and has a predetermined thickness, the channel layer 132 may have a high current density.

Meanwhile, in the process of etching the gate semiconductor material layer 160a using the etching gas EG containing nitrogen (N) or oxygen (O), an oxide film or a nitride film may be formed on the surface of the exposed gate structure 150. For example, as the nitrogen (N) or oxygen (O) contained in the etching gas EG flows into (and reacts with) the upper and side surfaces of the exposed first gate electrode 151, the first gate barrier layer 156 including an oxide film or a nitride film may be formed on the surface of the first gate electrode 151. In this case, in the process of etching the gate semiconductor material layer 160a, at least a portion of the first gate barrier layer 156 formed on the upper surface of the first gate electrode 151 may be removed together. In this case, the first gate barrier layer 156 may include a first portion disposed on the upper surface of the first gate electrode 151 and a second portion disposed on the side surface of the first gate electrode 151. Accordingly, the thickness of the first portion of the first gate electrode 151 may be smaller than the thickness of the second portion of the first gate electrode 151.

In the embodiment, the first gate barrier layer 156 may include an oxide film or a nitride film. For example, the first gate barrier layer 156 may include a metal nitride, a metal oxide, or a metal oxynitride. The material included in the first gate barrier layer 156 may be a conductive material. The first gate barrier layer 156 may include the same element as the material configuring the first gate electrode 151. For example, the first gate barrier layer 156 and the first gate electrode 151 may include a first material and a second material different from the first material, and the content of the first material of the first gate electrode 151 may be smaller than the content of the first material of the first gate barrier layer 156. In this case, the first material may include titanium (Ti), tantalum (Ta), aluminum (Al), or a combination thereof, and the second material may include nitrogen (N) or oxygen (O).

In addition, as the nitrogen (N) or oxygen (O) contained in the etching gas EG flows into (and reacts with) the exposed side surface of the second gate electrode 152, the second gate barrier layer 157 including the oxide film or the nitride film may be formed on the side surface of the second gate electrode 152. The second gate barrier layer 157 may include an oxide film or a nitride film. For example, the second gate barrier layer 157 may include a metal nitride, a metal oxide, or a metal oxynitride. The material included in the second gate barrier layer 157 may be a conductive material. The second gate barrier layer 157 may include the same element as the material configuring the second gate electrode 152. For example, the second gate barrier layer 157 and the second gate electrode 152 may include a first material and a second material different from the first material, and the content of the first material of the second gate electrode 152 may be smaller than the content of the first material of the second gate barrier layer 157. In this case, the first material may include titanium (Ti), tantalum (Ta), aluminum (Al), or a combination thereof, and the second material may include nitrogen (N) or oxygen (O).

Subsequently, though not shown in the drawings, the passivation layer 140 may be formed on the barrier layer 136 and the gate structure 150. Trenches may be formed by patterning the passivation layer 140 using a photo and etching process, and the source electrode 173 and the drain electrode 175 may be formed by forming a conductive material within the trenches. Accordingly, the semiconductor device according to the embodiment of FIG. 10 to FIG. 12 may be formed.

While the embodiment of the present disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device comprising:
a channel layer;
a barrier layer disposed on the channel layer and including a material having an energy band gap different from that of the channel layer;
a gate semiconductor layer disposed on the barrier layer;
a gate electrode pattern including a first gate electrode disposed on the gate semiconductor layer and a second gate electrode disposed between the first gate electrode and the gate semiconductor layer; and
a source electrode and a drain electrode disposed on both sides of the gate electrode pattern respectively and in contact with the channel layer,
wherein the first gate electrode includes:
a lower surface facing the gate semiconductor layer,
an upper surface extending horizontally in a first direction and arranged oppositely to the lower surface in a second direction crossing the first direction,
a side surface extending vertically the first direction, and
a first curved surface between the upper surface and the side surface of the first gate electrode, and a second curved surface between the lower surface and the side surface of the first gate electrode,
wherein a curvature of the first curved surface is smaller than that of the second curved surface.

2. The semiconductor device of claim 1, wherein in a vertical cross-sectional view, a width of the gate electrode pattern is greater than that of the gate semiconductor layer.

3. The semiconductor device of claim 2, wherein
in a horizontal direction, at least a portion of the first gate electrode protrudes from a side surface of the second gate electrode.

4. The semiconductor device of claim 1, wherein
in a vertical cross-sectional view, a width of the second gate electrode gradually decreases as a distance from an upper surface of the channel layer increases.

5. The semiconductor device of claim 1, wherein
in a vertical cross-sectional view, a width of the first gate electrode is different from that of the second gate electrode.

6. The semiconductor device of claim 1, wherein the gate electrode pattern further includes:
a third gate electrode disposed between the second gate electrode and the gate semiconductor layer, and
the third gate electrode includes a material different from that of the second gate electrode.

7. The semiconductor device of claim 6, wherein
in a vertical cross-sectional view, the third gate electrode includes a curved surface between a lower surface and the side surface of the third gate electrode.

8. The semiconductor device of claim 1, wherein the gate electrode pattern further includes:
a first gate barrier layer including a first portion disposed on the upper surface of the first gate electrode and a second portion disposed on the side surface of the first gate electrode, and
a thickness in a vertical direction of the first portion is smaller than a thickness in a horizontal direction of the second portion.

9. The semiconductor device of claim 8, wherein
the first gate barrier layer contains nitrogen (N) or oxygen (O).

10. The semiconductor device of claim 8, wherein:
the first gate electrode and the first gate barrier layer include a first material and a second material different from the first material, and
a content of the first material of the first gate electrode is smaller than that of the first material of the first gate barrier layer.

11. The semiconductor device of claim 10, wherein
the first material contains titanium (Ti) and the second material contains nitrogen (N).

12. The semiconductor device of claim 8, wherein:
the gate electrode pattern further includes a second gate barrier layer disposed on a side surface of the second gate electrode, and
the second gate barrier layer contains N or O.

13. The semiconductor device of claim 8, wherein
a width of the gate semiconductor layer gradually increases as a distance from the upper surface of the channel layer increases.

14. A semiconductor device comprising:
a channel layer;
a barrier layer disposed on the channel layer and including a material having an energy band gap different from that of the channel layer;
a gate semiconductor layer disposed on the barrier layer;
a gate electrode pattern including a first gate electrode disposed on the gate semiconductor layer and a second gate electrode disposed between the first gate electrode respectively and the gate semiconductor layer; and
a source electrode and a drain electrode disposed on both sides of the gate electrode pattern and in contact with the channel layer,
wherein the first gate electrode includes:
a lower surface facing the gate semiconductor layer,
an upper surface extending horizontally in a first direction and arranged oppositely to the lower surface in a second direction crossing the first direction,
a side surface extending vertically the first direction, and wherein, in a vertical cross-sectional view, a width of the first gate electrode or a width of the second gate electrode is greater than that of the gate semiconductor layer.

15. The semiconductor device of claim 14, wherein
in a vertical cross-sectional view, the width of the first gate electrode is different from that of the second gate electrode.

16. The semiconductor device of claim 14, wherein the gate electrode pattern further includes:
a first gate barrier layer including a first portion disposed on the upper surface of the first gate electrode and a second portion disposed on the side surface of the first gate electrode, and
a second gate barrier layer disposed on a side surface of the second gate electrode, and
a thickness in a vertical direction of the first portion of the first gate barrier layer is smaller than a thickness in a horizontal direction of the second portion of the first gate barrier layer.

17. The semiconductor device of claim 16, wherein
a thickness in a vertical direction of the first portion is smaller than that a thickness in a horizontal direction of the second gate barrier layer.

18. The semiconductor device of claim 16, wherein the first gate barrier layer includes:
a third curved surface between an upper surface and a side surface of the first gate barrier layer, and a fourth curved surface between a lower surface and the side surface of the first gate barrier layer, and
a curvature of the third curved surface is smaller than that of the fourth curved surface.

19. The semiconductor device of claim 16, wherein
each of the first gate barrier layer and the second gate barrier layer contains N or O.

20. A semiconductor device comprising:
a channel layer containing GaN;
a barrier layer disposed on the channel layer and containing AlGaN;
a gate semiconductor layer disposed on the barrier layer and containing p-type GaN;
a gate electrode pattern including a first gate electrode disposed on the gate semiconductor layer and a second gate electrode disposed between the first gate electrode and the gate semiconductor layer and protruding from a side surface of the gate semiconductor layer;
a source electrode and a drain electrode disposed on both sides of the gate electrode pattern respectively and in contact with the channel layer; and
a passivation layer covering the barrier layer and the gate electrode pattern,
wherein the first gate electrode includes:
a lower surface facing the gate semiconductor layer,
an upper surface extending in a first direction and arranged oppositely to the lower surface in a second direction crossing the first direction,
a side surface extending the first direction,
a first curved surface between the upper surface and the side surface of the first gate electrode, and
a second curved surface between the lower surface and the side surface of the first gate electrode, and
wherein a curvature of the first curved surface is smaller than that of the second curved surface.
